(19) United States
(12) Patent Application Publication
(10) Pub. No.: US 2026/0056470 A1
(43) Pub. Date: Feb. 26, 2026

(54) NEGATIVE RESIST COMPOSITION, AND METHOD FOR PRODUCING RESIST PATTERN

(71) Applicant: SUMITOMO CHEMICAL COMPANY, LIMITED, Tokyo (JP)

(72) Inventors: Suguru TANIGUCHI, Osaka (JP); Masako Sugihara, Osaka (JP)

(73) Assignee: SUMITOMO CHEMICAL COMPANY, LIMITED, Tokyo (JP)

(21) Appl. No.: 19/307,468

(22) Filed: Aug. 22, 2025

(30) Foreign Application Priority Data
Aug. 26, 2024 (JP) 2024-144478

(51) Int. Cl. G03F 7/038; C08F 16/22; G03F 7/004; G03F 7/16

(52) U.S. Cl. CPC G03F 7/0388; C08F 16/22; G03F 7/0046; G03F 7/0382; G03F 7/168

(57) ABSTRACT

A negative resist composition includes a resin (A1) including a structural unit represented by formula (a2-1) and a structural unit represented by formula (a2-4), a novolak resin (A2), a resin (A3) including a structural unit represented by formula (a3-1) and a structural unit represented by formula (a3-2), a crosslinking agent (E) and an acid generator (B):

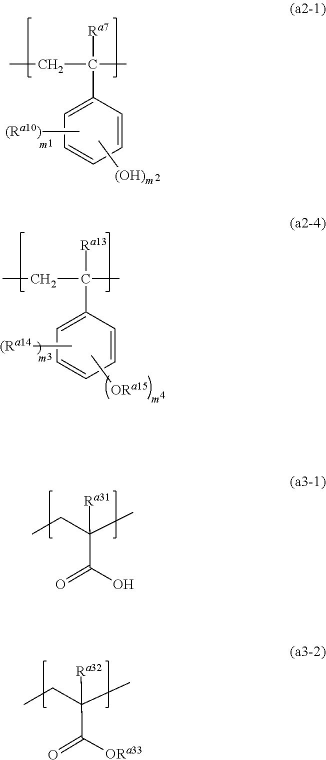

### BACKGROUND OF THE INVENTION

### Field of the Invention

The present invention relates to a negative resist composition and a method for producing a resist pattern.

### Description of the Related Art

JP 2001-42529 A mentions a negative resist composition comprising a partially ethyl-etherified polyvinylphenol and a m-cresol novolak resin.

### SUMMARY OF THE INVENTION

When using a negative resist composition as mentioned in JP 2001-42529 A to form a thick resist pattern having a film thickness of 5 μm or more, the resolution after development was sometimes insufficient.

Thus, an object of the present invention is to provide a negative resist composition capable of forming a resist pattern with excellent resolution. Another object of the present invention is to provide a method for producing a resist pattern using the negative resist composition.

The present inventors have intensively studied to solve the above problems and found that the above problems can be solved by a negative resist composition comprising a resin (A1), a novolak resin (A2), a resin (A3), an acid generator (B) and a crosslinking agent (E), the resin (A3) including a prescribed structural unit. Further study led to completion of the present invention.

Namely, the present invention relates to the following negative resist compositions and method for producing the same.
[1]A negative resist composition comprising a resin (A1) including a structural unit represented by formula (a2-1) and a structural unit represented by formula (a2-4), a novolak resin (A2), a resin (A3) including a structural unit represented by formula (a3-1) and a structural unit represented by formula (a3-2), a crosslinking agent (E) and an acid generator (B):

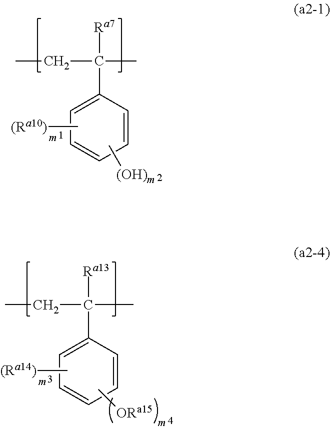

wherein, in formula (a2-1) and formula (a2-4),
   R^{a7} and R^{a13} each independently represent a hydrogen atom or a methyl group,
   R^{a10} and R^{a14} each independently represent an alkyl group having 1 to 6 carbon atoms,
   R^{a15} represents a hydrocarbon group having 1 to 12 carbon atoms, and a methylene group included in the hydrocarbon group may be replaced by an oxygen atom or a carbonyl group,
   m¹ represents an integer of 0 to 4, and when m¹ is 2 or more, a plurality of R^{a10} may be the same or different from each other,
   m² represents an integer of 1 to 4,
   in which the total of m¹ and m² is 5 or less,
   m³ represents an integer of 0 to 4, and when m³ is 2 or more, a plurality of R^{a14} may be the same or different from each other, and
   m⁴ represents an integer of 1 to 4, and when m⁴ is 2 or more, a plurality of R^{a15} may be the same or different from each other,
   in which the total of m³ and m⁴ is 5 or less, and:

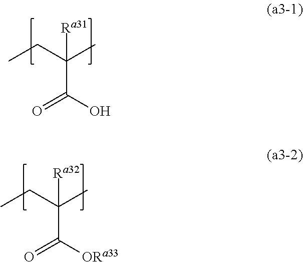

wherein, in formula (a3-1) and formula (a3-2),
   R^{a31} and R^{a32} each independently represent a hydrogen atom or a methyl group, and
   R^{a33} represents an alkyl group having 1 to 12 carbon atoms, and a methylene group included in the alkyl group may be replaced by an oxygen atom.
[2] The negative resist composition according to [1], wherein the acid generator (B) is a compound having a group represented by formula (B1):

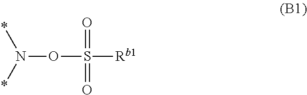

wherein, in formula (B1),
   R^{b1} represents a hydrocarbon group having 1 to 18 carbon atoms which may have a fluorine atom, and a methylene group included in the hydrocarbon group may be replaced by an oxygen atom or a carbonyl group, and * represents a bond.
[3] The negative resist composition according to [1] or [2], wherein the resin (A3) is composed of a structural unit represented by formula (a3-1) and a structural unit represented by formula (a3-2).
[4] The negative resist composition according to any one of [1] to [3], wherein the crosslinking agent (E) is a melamine-based crosslinking agent or a glycoluril-based crosslinking agent.
[5]A method for producing a resist pattern, which comprises:
(1) a step of applying the negative resist composition according to any one of any one of [1] to [4] on a substrate,
(2) a step of drying the applied composition to form a composition layer,
(3) a step of exposing the composition layer, and
(4) a step of heating and developing the exposed composition layer.

According to the present invention, it is possible to obtain a negative resist composition with satisfactory resolution.

### DETAILED DESCRIPTION OF THE PREFERRED EMBODIMENTS

In the present specification, unless otherwise specified, in the description of a structural formula of a compound, “hydrocarbon group” means a linear or branched chain hydrocarbon group, an alicyclic hydrocarbon group, an aromatic hydrocarbon group, and a group obtained by combining these groups. “Alicyclic hydrocarbon group” means a group in which the number corresponding to the valence of hydrogen atoms are eliminated from the ring of an alicyclic hydrocarbon. When stereoisomers exist, “hydrocarbon group” includes all stereoisomers.

In the present specification, “(meth)acrylic acid” means “at least one of acrylic acid and methacrylic acid”, and “(meth)acrylate” means “at least one of acrylate and methacrylate”.

In groups mentioned in the present specification, those that can take both linear and branched structures are interpreted to include both.

In the present specification, “solid content of negative resist composition” means the total of contents in which the below-mentioned solvent (D) is removed from the total amount of the negative resist composition.

### 1. Negative Resist Composition

The negative resist composition of the present invention includes a resin including a structural unit represented by formula (a2-1) (hereinafter sometimes referred to as structural unit (a2-1)) and a structural unit represented by formula (a2-4) (hereinafter sometimes referred to as structural unit (a2-4)) (hereinafter sometimes referred to as “resin (A1)”), a novolak resin (hereinafter sometimes referred to as “resin (A2)”), a resin including a structural unit represented by formula (a3-1) (hereinafter sometimes referred to as structural unit (a3-1)) and a structural unit represented by formula (a3-2) (hereinafter sometimes referred to as structural unit (a3-2)) (hereinafter sometimes referred to as “resin (A3)”), a crosslinking agent (hereinafter sometimes referred to as “crosslinking agent (E)”), and an acid generator (hereinafter sometimes referred to as “acid generator (B)”).

Further, the negative resist composition of the present invention may also include a quencher (hereinafter sometimes referred to as “quencher (C)”), a solvent (hereinafter sometimes referred to as “solvent (D)”), and other components (hereinafter sometimes referred to as “other components (F)”), if necessary.

### <Resin (A1)>

The resin (A1) is a resin including a structural unit (a2-1) and a structural unit (a2-4), which is an alkali-soluble resin:

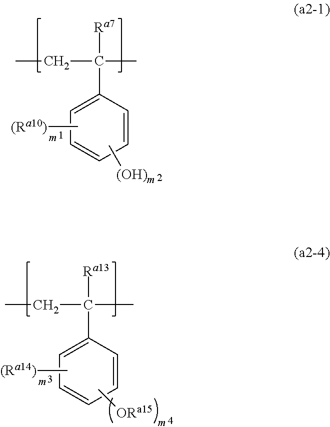

wherein, in formula (a2-1) and formula (a2-4),
R^{a7} and R^{a13} each independently represent a hydrogen atom or a methyl group,
R^{a10} and R^{a14} each independently represent an alkyl group having 1 to 6 carbon atoms,
R^{a15} represents a hydrocarbon group having 1 to 12 carbon atoms, and a methylene group included in the hydrocarbon group may be replaced by an oxygen atom or a carbonyl group,
m¹ represents an integer of 0 to 4, and when m¹ is 2 or more, a plurality of R^{a10} may be the same or different from each other,
m² represents an integer of 1 to 4,
in which the total of m¹ and m² is 5 or less,
m³ represents an integer of 0 to 4, and when m³ is 2 or more, a plurality of R^{a14} may be the same or different from each other, and
m⁴ represents an integer of 1 to 4, and when m⁴ is 2 or more, a plurality of R^{a15} may be the same or different from each other,
in which the total of m³ and m⁴ is 5 or less.

Examples of the alkyl group having 1 to 6 carbon atoms represented by R^{a10} and R^{a14} include a methyl group, an ethyl group, a propyl group, a butyl group, a pentyl group, a hexyl group and the like. The alkyl group having 1 to 6 carbon atoms preferably has 1 to 4 carbon atoms, and more preferably 1 to 3 carbon atoms.

R^{a10} and R^{a14} are each independently preferably an alkyl group having 1 to 4 carbon atoms, more preferably an alkyl group having 1 to 3 carbon atoms, still more preferably a methyl group or an ethyl group, and yet more preferably a methyl group.

m¹ and m³ are each independently preferably an integer of 0 to 2, and more preferably 0 or 1.

Examples of the hydrocarbon group having 1 to 12 carbon atoms represented by R^{a15} include a chain hydrocarbon group having 1 to 12 carbon atoms (an alkyl group, an alkenyl group and an alkynyl group), an alicyclic hydrocarbon group having 3 to 12 carbon atoms, an aromatic hydrocarbon group having 6 to 12 carbon atoms, and a group having 4 to 12 carbon atoms formed by combining these groups.

Examples of the alkyl group having 1 to 12 carbon atoms include a methyl group, an ethyl group, an n-propyl group, an isopropyl group, an n-butyl group, a sec-butyl group, an isobutyl group, an n-pentyl group, an n-hexyl group, an n-heptyl group, an n-octyl group, an n-nonyl group, an n-decyl group and the like.

Examples of the alkenyl group having 2 to 12 carbon atoms include an ethenyl group, a propenyl group, an isopropenyl group, a butenyl group, an isobutenyl group, a tert-butenyl group, a pentenyl group, a hexenyl group, a heptenyl group, an octenyl group, an isooctenyl group, a nonenyl group and the like.

Examples of the alkynyl group having 2 to 12 carbon atoms include an ethynyl group, a propynyl group, an isopropynyl group, a butynyl group, an isobutynyl group, a tert-butynyl group, a pentynyl group, a hexynyl group, an octynyl group, a nonynyl group and the like.

The chain hydrocarbon group having 1 to 12 carbon atoms preferably has 1 to 10 carbon atoms, more preferably 1 to 8 carbon atoms, and still more preferably 1 to 6 carbon atoms.

The alicyclic hydrocarbon group having 3 to 12 carbon atoms may be either monocyclic or polycyclic. Examples of the monocyclic alicyclic hydrocarbon group include cycloalkyl groups such as a cyclopentyl group, a cyclohexyl group, a cycloheptyl group and a cyclooctyl group. Examples of the polycyclic alicyclic hydrocarbon group include a decahydronaphthyl group, an adamantyl group, a norbornyl group, and the following groups (* represents a bond).

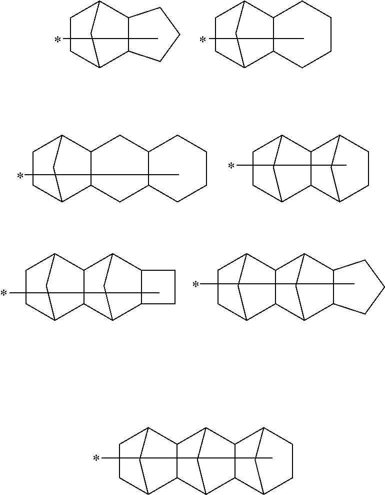

The alicyclic hydrocarbon group having 3 to 12 carbon atoms preferably has 3 to 10 carbon atoms, and more preferably 3 to 8 carbon atoms.

Examples of the aromatic hydrocarbon group having 6 to 12 carbon atoms include a phenyl group, a naphthyl group and the like. The aromatic hydrocarbon group having 6 to 12 carbon atoms preferably has 6 to 10 carbon atoms.

Regarding the group having 4 to 12 carbon atoms formed by combining the above groups, examples of the group obtained by combining an alkyl group with an alicyclic hydrocarbon group (a group having 4 to 12 carbon atoms) include a methylcyclohexyl group, a dimethylcyclohexyl group, a methylnorbornyl group, a cyclohexylmethyl group, an adamantylmethyl group, a norbornylethyl group and the like.

The group obtained by combining an alkyl group with an aromatic hydrocarbon group (a group having 7 to 12 carbon atoms) is, for example, an aralkyl group and an aromatic hydrocarbon group having an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, a 2-methyl-6-ethylphenyl group and the like.

The group obtained by combining an alicyclic hydrocarbon group with an aromatic hydrocarbon group (a group having 9 to 12 carbon atoms) is, for example, an aromatic hydrocarbon group having an alicyclic hydrocarbon group and an alicyclic hydrocarbon group having an aromatic hydrocarbon group, and specific examples thereof include a p-cyclohexylphenyl group, a phenylcyclohexyl group and the like.

The hydrocarbon group having 1 to 12 carbon atoms represented by R^{a15} excludes a group in which a carbon atom bonded to an oxygen atom is a tertiary carbon atom. A methylene group included in the hydrocarbon group having 1 to 12 carbon atoms may be substituted with an oxygen atom or a carbonyl group, in which a methylene group bonded to an oxygen atom and a methylene group bonded to the methylene group in formula (a2-4) are not substituted with an oxygen atom. R^{a15} does not include an acid-labile group. The “acid-labile group” means a group having a leaving group (sometimes referred to as leaving group) which can be eliminated by contact with an acid.

R^{a15} is preferably an alkyl group having 1 to 8 carbon atoms, an alicyclic hydrocarbon group having 3 to 10 carbon atoms, an aromatic hydrocarbon group having 6 to 10 carbon atoms, or a group having 6 to 10 carbon atoms formed by combining these groups, more preferably an alkyl group having 1 to 6 carbon atoms, still more preferably an alkyl group having 1 to 4 carbon atoms, and yet more preferably a methyl group, an ethyl group or a propyl group.

R^{a7} and R^{a13} are each independently preferably a hydrogen atom.

m² and m⁴ are each independently preferably an integer of 1 to 3, and more preferably 1 or 2.

In the resin (A1), the content of the structural unit (a2-1) is preferably 2 to 99 mol %, more preferably 5 to 98 mol %, still more preferably 10 to 90 mol %, yet more preferably 20 to 85 mol %, further preferably 40 to 85 mol %, and further more preferably 75 to 85 mol %, based on all structural units of the resin (A1).

In the resin (A1), the content of the structural unit (a2-4) is preferably 1 to 98 mol %, more preferably 2 to 95 mol %, still more preferably 3 to 40 mol %, yet more preferably 5 to 30 mol %, further preferably 10 to 25%, and still further preferably 15 to 25 mol %, based on all structural units of the resin (A1).

The resin (A1) may include structural units other than the structural units (a2-1) and (a2-4). Examples of such structural unit include a structural unit of a monomer in which a hydroxy group of hydroxystyrene is substituted with other groups or atoms, and a structural unit of a monomer having an α,β-unsaturated double bond.

Examples of the monomer that forms such structural unit include styrene-based monomers such as styrene, chlorostyrene and α-methylstyrene; acrylic acid monomers such as acrylic acid, methacrylic acid, methyl acrylate and methyl methacrylate; and vinyl acetate-based monomers such as vinyl acetate and vinyl benzoate.

It is possible to produce the resin (A1), for example, by the method mentioned in JP 7-295220 A.

The weight-average molecular weight of the resin (A1) is preferably 1,000 or more, more preferably 1,500 or more, and still more preferably 2,000 or more, and is preferably 10,000 or less, more preferably 8,000 or less, and still more preferably 5,000 or less. The weight-average molecular weight is determined as a standard polystyrene conversion value by gel permeation chromatography. The detailed analysis conditions of this analysis are mentioned in Examples of the present application.

The content of the resin (A1) is preferably 10% by mass or more, more preferably 15% by mass or more, and still more preferably 20% by mass or more, and is preferably 90% by mass or less, more preferably 80% by mass or less, still more preferably 70% by mass or less, and yet more preferably 65% by mass or less, based on the total amount of the resin included in the negative resist composition of the present invention.

### <Novolak Resin (A2)>

The novolak resin (A2) is a resin obtained by condensing a phenol compound with aldehyde in the presence of a catalyst, for example, a resin including a structural unit represented by the following formula (a4):

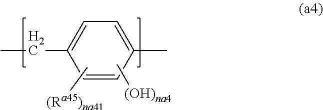

wherein, in formula (a4),
R^{a45} represents a halogen atom, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkoxyalkoxy group having 2 to 12 carbon atoms, an alkylcarbonyl group having 2 to 4 carbon atoms, an alkylcarbonyloxy group having 2 to 4 carbon atoms, an acryloyloxy group or a methacryloyloxy group,
na4 represents an integer of 1 to 4, and
na41 represents an integer of 0 to 3, and when na41 is 2 or more, a plurality of R^{a45} may be the same or different from each other, in which na4 and na41 satisfy: 1≤na4+na41≤4.

In formula (a4), examples of the halogen atom as for R^{a45} include a fluorine atom, a chlorine atom, a bromine atom and an iodine atom.

The alkyl group having 1 to 6 carbon atoms as for R^{a45} may be linear or branched alkyl group, and examples thereof include a methyl group, an ethyl group, a propyl group, a butyl group, a pentyl group, a hexyl group and the like.

Examples of the haloalkyl group having 1 to 6 carbon atoms as for R^{a45} include groups in which a hydrogen atom included in the alkyl group is substituted with the halogen atom, for example, an alkyl fluoride group having 1 to 6 carbon atoms, an alkyl chloride group having 1 to 6 carbon atoms, an alkyl bromide group having 1 to 6 carbon atoms or an alkyl iodide group having 1 to 6 carbon atoms, of which a perfluoroalkyl group having 1 to 3 carbon atoms is preferable.

Examples of the alkoxy group having 1 to 6 carbon atoms as for R^{a45} include a methoxy group, an ethoxy group, a propoxy group, an isopropoxy group, a butoxy group, a sec-butoxy group, a tert-butoxy group and the like. The number of carbon atoms of the alkoxy group is preferably 1 to 4, more preferably 1 to 3, still more preferably a methoxy group or an ethoxy group, and yet more preferably a methoxy group.

Examples of the alkoxyalkyl group having 2 to 12 carbon atoms as for R^{a45} include a methoxymethyl group, an ethoxyethyl group, a propoxymethyl group, an isopropoxymethyl group, a butoxymethyl group, a sec-butoxymethyl group, a tert-butoxymethyl group and the like. The alkoxyalkyl group is preferably an alkoxyalkyl group having 2 to 8 carbon atoms, more preferably a methoxymethyl group or an ethoxyethyl group, and still more preferably a methoxymethyl group.

Examples of the alkoxyalkoxy group having 2 to 12 carbon atoms as for R^{a45} include a methoxymethoxy group, a methoxyethoxy group, an ethoxymethoxy group, an ethoxyethoxy group, a propoxymethoxy group, an isopropoxymethoxy group, a butoxymethoxy group, a sec-butoxymethoxy group, a tert-butoxymethoxy group and the like. The alkoxyalkoxy group is preferably an alkoxyalkoxy group having 2 to 8 carbon atoms, and more preferably a methoxyethoxy group or an ethoxyethoxy group.

Examples of the alkylcarbonyl group having 2 to 4 carbon atoms as for R^{a45} include an acetyl group, a propionyl group and a butyryl group. The alkylcarbonyl group is preferably an alkylcarbonyl group having 2 to 3 carbon atoms, and more preferably an acetyl group.

Examples of the alkylcarbonyloxy group having 2 to 4 carbon atoms as for R^{a45} include an acetyloxy group, a propionyloxy group, a butyryloxy group and the like. The alkylcarbonyloxy group is preferably an alkylcarbonyloxy group having 2 to 3 carbon atoms, and more preferably an acetyloxy group.

In formula (a4), R^{a45} is preferably an alkyl group having 1 to 4 carbon atoms or an alkoxy group having 1 to 4 carbon atoms, more preferably an alkyl group having 1 to 3 carbon atoms or an alkoxy group having 1 to 3 carbon atoms, still more preferably a methyl group, an ethyl group, a methoxy group or an ethoxy group, and yet more preferably a methyl group or a methoxy group.

na4 is preferably 1 or 2, and more preferably 1.

na41 is preferably 0, 1 or 2, and more preferably 0 or 1.

The weight-average molecular weight of the novolak resin (A2) is preferably 1,000 or more, more preferably 1,500 or more, still more preferably 2,000 or more, and yet more preferably 3,000 or more, and is preferably 20,000 or less, more preferably 15,000 or less, still more preferably 13,000 or less, yet more preferably 11,000 or less, and further preferably 10,000 or less. By setting the weight-average molecular weight within this range, it is possible to effectively prevent the film from thinning and leaving residue after the development. The weight-average molecular weight is determined as a standard polystyrene conversion value by gel permeation chromatography. The detailed analysis conditions of this analysis are mentioned in Examples of the present application.

The content of the resin (A2) is preferably 5% by mass or more, more preferably 10% by mass or more, and still more preferably 20% by mass or more, and is preferably 90% by mass or less, more preferably 80% by mass or less, still more preferably 70% by mass or less, and yet more preferably 65% by mass or less, based on the total amount of the resin included in the negative resist composition of the present invention.

### <Resin (A3)>

The resin (A3) is a resin including a structural unit represented by formula (a3-1) and a structural unit represented by formula (a3-2), which is an alkali-soluble resin:

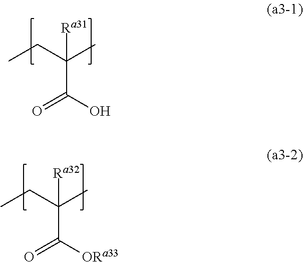

wherein, in formula (a3-1) and formula (a3-2),
R^{a31} and R^{a32} each independently represent a hydrogen atom or a methyl group, and
R^{a33} represents an alkyl group having 1 to 12 carbon atoms, and a methylene group included in the alkyl group may be replaced by an oxygen atom.

Examples of the alkyl group having 1 to 12 carbon atoms represented by R^{a33} include the same as an alkyl group having 1 to 12 carbon atoms of the hydrocarbon group having 1 to 12 carbon atoms represented by R^{a15}.

The alkyl group having 1 to 12 carbon atoms represented by R^{a33} excludes a group in which in which a carbon atom bonded to an oxygen atom is a tertiary carbon atom. A methylene group included in the alkyl group having 1 to 12 carbon atoms may be substituted with an oxygen atom, in which a methylene group bonded to an oxygen atom and a methylene group bonded to the methylene group in formula (a3-2) are not substituted with an oxygen atom. R^{a33} does not include an acid-labile group.

R^{a33} is preferably an alkyl group having 1 to 8 carbon atoms, more preferably an alkyl group having 1 to 6 carbon atoms, still more preferably an alkyl group having 1 to 4 carbon atoms, and yet more preferably a methyl group, an ethyl group or a propyl group.

R^{a31} is preferably a methyl group, and R^{a32} is preferably a hydrogen atom or a methyl group.

In the resin (A3), the content of the structural unit (a3-1) is preferably 2 to 60 mol %, more preferably 3 to 50 mol %, still more preferably 5 to 40 mol %, and yet more preferably 10 to 30 mol %, based on all structural units of the resin (A3).

In the resin (A3), the content of the structural unit (a3-2) is preferably 40 to 98 mol %, more preferably 50 to 97 mol %, still more preferably 60 to 95 mol %, and yet more preferably 70 to 90 mol %, based on all structural units of the resin (A3).

The resin (A3) may include structural units conventionally known in the relevant field other than the structural unit (a3-1) and the structural unit (a3-2), and is preferably a resin including only the structural unit (a3-1) and the structural unit (a3-2).

The resin (A3) can be produced by polymerizing a monomer from which a structural unit derived from acrylic acid, methacrylic acid or an acrylic acid alkyl ester are derived, and a monomer from which a structural unit derived from a methacrylic acid alkyl ester is derived using a polymerization method (e.g., radical polymerization method).

The content of each structural unit included in the resin (A3) can be adjusted by the amount of each monomer used for polymerization.

Examples of the monomer from which a structural unit derived from an acrylic acid alkyl ester is derived include methyl acrylate, ethyl acrylate, propyl acrylate, tert-butyl acrylate, hexyl acrylate and the like.

Examples of the monomer from which a structural unit derived from a methacrylic acid alkyl ester is derived include methyl methacrylate, ethyl methacrylate, propyl methacrylate, tert-butyl methacrylate, hexyl methacrylate and the like.

The weight-average molecular weight of the resin (A3) is preferably 3,000 or more, more preferably 5,000 or more, and still more preferably 8,000 or more, and is preferably 100,000 or less, more preferably 80,000 or less, still more preferably 50,000 or less, yet more preferably 30,000 or less, and particularly preferably 20,000 or less. The weight-average molecular weight is determined as a standard polystyrene conversion value by gel permeation chromatography. The detailed conditions of this analysis are mentioned in Examples of the present application.

The content of the resin (A3) is preferably 3% by mass or more, more preferably 5% by mass or more, and still more preferably 10% by mass or more, and is preferably 50% by mass or less, more preferably 40% by mass or less, still more preferably 35% by mass or less, and yet more preferably 30% by mass or less, based on the total amount of the resin included in the negative resist composition of the present invention.

In the resin (A3), the content of the structural unit in which R^{a31} is a hydrogen atom or a methyl group (particularly, a methyl group) in the structural unit (a3-1) is preferably 10 mol % or more, more preferably 15 mol % or more, and still more preferably 18 mol % or more, based on resin (A3), from the viewpoint of capable of suppressing generation of the residue after development of the resist.

In the resin (A3), it is preferable to include both a structural unit in which R^{a32} is a hydrogen atom in the structural unit (a3-2), and a structural unit in which R^{a32} is a methyl group. In that case, the content of the structural unit in which R^{a32} is a hydrogen atom in the structural unit (a3-2) is preferably 35 mol % or more, and more preferably 45 mol % or more, and is preferably 65 mol % or less, and more preferably 55 mol % or less.

### <Acid Generator (B)>

The acid generator (B) is a compound capable of generating an acid by decomposing upon light irradiation (exposure). The acid thus generated acts as an acid catalyst which accelerates a crosslinking reaction, and thus a crosslinking agent can bond with a reactive group in the resin to form crosslinks. In other words, by exposing the negative resist composition including the resin (A1), a resist is made insoluble in a developer (an aqueous alkali solution).

Either nonionic or ionic acid generator may be used as the acid generator (B).

Examples of the nonionic acid generator include organic halides, sulfonate esters (e.g., 2-nitrobenzyl ester, aromatic sulfonates, oxysulfonates, N-sulfonyloxyimides, sulfonyloxyketones, diazonaphthoquinone 4-sulfonates), sulfones (e.g., disulfone, ketosulfone, sulfonyldiazomethane) and the like.

As the ionic acid generator, for example, onium salts containing onium cations (e.g., diazonium salts, phosphonium salts, sulfonium salts, iodonium salts) are typical. Examples of anions of onium salts include sulfonic acid anions, sulfonylimide anions, sulfonylmethide anion and the like.

It is possible to use, as other acid generators (B), compounds generating an acid upon exposure to radiation mentioned in JP 63-26653 A, JP 55-164824 A, JP 62-69263 A, JP 63-146038 A, JP 63-163452 A, JP 62-153853 A, JP 63-146029 A, U.S. Pat. Nos. 3,779,778, 3,849,137, DE Patent No. 3914407, EP Patent No. 126,712 and the like. Compounds produced by known methods may also be used. The acid generators (B) may be used alone, or two or more thereof may be used in combination.

The nonionic acid generator is preferably a compound having a group represented by formula (B1) (* represents a bond).

When the acid generator (B) contains two or more types of compounds having a group represented by formula (B1), at least one of them is preferably a compound represented by the below-mentioned formula (b1):

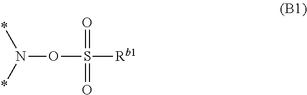

wherein, in formula (B1),
R^{b1} represents a hydrocarbon group having 1 to 18 carbon atoms which may have a fluorine atom, a methylene group included in the hydrocarbon group may be replaced by an oxygen atom or a carbonyl group, and * represents a bond.

Examples of the hydrocarbon group having 1 to 18 carbon atoms in hydrocarbon group having 1 to 18 carbon atoms which may have a fluorine atom as for R^{b1} include a linear or branched chain hydrocarbon group having 1 to 18 carbon atoms, an alicyclic hydrocarbon group having 3 to 18 carbon atoms, an aromatic hydrocarbon group having 6 to 18 carbon atoms, and a group having 4 to 18 carbon atoms obtained by combining these groups.

The linear or branched chain hydrocarbon group having 1 to 18 carbon atoms is preferably an alkyl group having 1 to 18 carbon atoms, and examples thereof include a methyl group, an ethyl group, a propyl group, a butyl group, a pentyl group, a hexyl group, a heptyl group, an octyl group, a nonyl group, a decyl group and the like. Of these, a linear hydrocarbon group is preferable.

Examples of the alicyclic hydrocarbon group having 3 to 18 carbon atoms include a cyclopropyl group, a cyclobutyl group, a cyclopentyl group, a cyclohexyl group, a cycloheptyl group, a cyclooctyl group, an adamantyl group and the like.

The aromatic hydrocarbon group having 6 to 18 carbon atoms is preferably an aryl group having 6 to 18 carbon atoms, and examples thereof include aryl groups such as a phenyl group, a naphthyl group, an anthryl group, a biphenyl group and a phenanthryl group.

Examples of the group obtained by combining a chain hydrocarbon group with an alicyclic hydrocarbon group (the group having 4 to 18 carbon atoms) among the group having 4 to 18 carbon atoms obtained by combining the above groups include a methylcyclohexyl group, a dimethylcyclohexyl group, a methylnorbornyl group, an isobornyl group, a 2-alkyladamantan-2-yl group, a 1-(adamantan-1-yl)alkan-1-yl group and the like.

The group obtained by combining a chain hydrocarbon group with an aromatic hydrocarbon group (the group having 7 to 18 carbon atoms) is, for example, an aralkyl group or an aromatic hydrocarbon group having an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, a 2-methyl-6-ethylphenyl group and the like.

The group obtained by combining an alicyclic hydrocarbon group with an aromatic hydrocarbon group (the group having 9 to 18 carbon atoms) is, for example, an aromatic hydrocarbon group having an alicyclic hydrocarbon group or an alicyclic hydrocarbon group having an aromatic hydrocarbon group, and specific examples thereof include a p-cyclohexylphenyl group, a p-adamantylphenyl group, a phenylcyclohexyl group and the like.

Of the hydrocarbon group having 1 to 18 carbon atoms represented by R^{b1}, an alkyl group having 1 to 10 carbon atoms or an aromatic hydrocarbon group having 6 to 10 carbon atoms is preferable, an alkyl group having 1 to 8 carbon atoms is more preferable, and an alkyl group having 1 to 4 carbon atoms is still more preferable.

Examples of the group in which a methylene group included in the alicyclic hydrocarbon group having 3 to 18 carbon atoms in R^{b1} is replaced by an oxygen atom or a carbonyl group include groups represented by formula (Y1) to formula (Y12). Groups represented by formula (Y7) to formula (Y9) are preferable, and a group represented by formula (Y9) is more preferable.

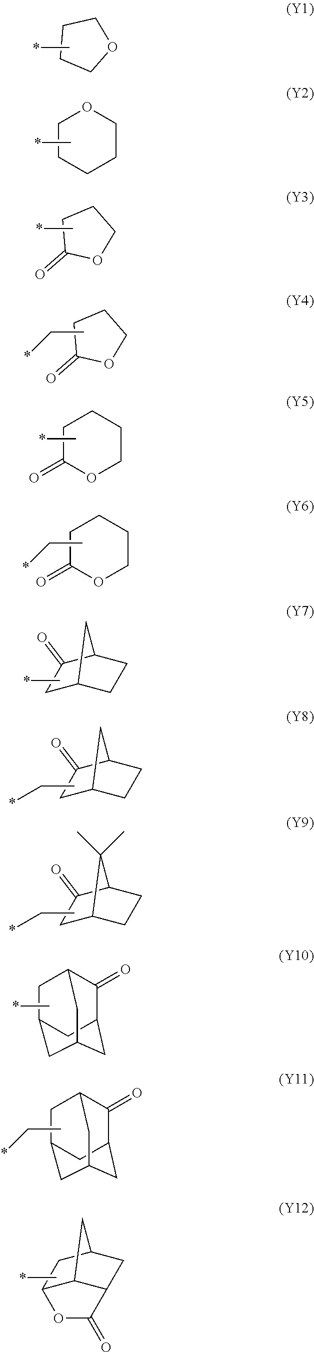

The hydrocarbon group having 1 to 18 carbon atoms which has a fluorine atom is a group in which one or more hydrogen atoms included in the hydrocarbon group having 1 to 18 carbon atoms are substituted with a fluorine atom, and specific examples thereof include fluoroalkyl groups such as a fluoromethyl group, a fluoroethyl group, a fluoropropyl group, a fluorobutyl group, a fluoropentyl group, a fluorohexyl group, a fluoroheptyl group, a fluorooctyl group, a fluorononyl group and a fluorodecyl group; fluorocycloalkyl groups such as a fluorocyclopropyl group, a fluorocyclobutyl group, a fluorocyclopentyl group, a fluorocyclohexyl group, a fluorocycloheptyl, a fluorocyclooctyl group and a fluoroadamantyl group; and fluoroaryl groups such as a fluorophenyl group, a fluoronaphthyl group and a fluoroanthryl group.

The hydrocarbon group having 1 to 18 carbon atoms which has a fluorine atom is preferably an alkyl group having 1 to 10 carbon atoms which has a fluorine atom, or an aromatic hydrocarbon group having 6 to 10 carbon atoms which has a fluorine atom, more preferably a perfluoroalkyl group having 1 to 8 carbon atoms, and still more preferably a perfluoroalkyl group having 1 to 4 carbon atoms.

Examples of the compound having a group represented by formula (B1) include a compound represented by formula (b1).

When including two or more types of compounds having a group represented by formula (B1), at least one of them is preferably a compound represented by formula (b1):

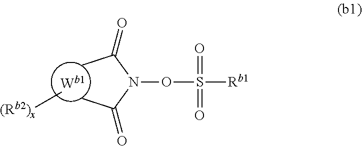

wherein, in formula (b1),
R^{b1} is the same as defined above,
R^{b2} represents a hydrocarbon group having 1 to 12 carbon atoms, an alkoxy group having 1 to 8 carbon atoms, or a thioalkyl group having 1 to 8 carbon atoms,
ring W^{b1} represents an aromatic hydrocarbon ring having 6 to 14 carbon atoms, or an aromatic heterocyclic ring having 6 to 14 carbon atoms, and
x represents an integer of 0 to 6, and when x is 2 or more, a plurality of R^{b2} may be the same or different.

The hydrocarbon group having 1 to 12 carbon atoms represented by R^{b2} may be either linear or branched, and examples thereof include an alkyl group having 1 to 12 carbon atoms, an alkenyl group having 2 to 12 carbon atoms and an alkynyl group having 2 to 12 carbon atoms. The hydrocarbon group is preferably a hydrocarbon group having 1 to 8 carbon atoms, more preferably an alkyl group having 1 to 8 carbon atoms, an alkenyl group having 2 to 8 carbon atoms or an alkynyl group having 2 to 8 carbon atoms, still more preferably an alkyl group having 1 to 6 carbon atoms or an alkynyl group having 2 to 6 carbon atoms, and yet more preferably an alkyl group having 1 to 4 carbon atoms.

Examples of the alkyl group having 1 to 12 carbon atoms include a methyl group, an ethyl group, an n-propyl group, an isopropyl group, an n-butyl group, a sec-butyl group, an isobutyl group, an n-pentyl group, an n-hexyl group, an n-heptyl group, an n-octyl group, an n-nonyl group, an n-decyl group and the like.

Examples of the alkenyl group having 2 to 12 carbon atoms include an ethenyl group, a propenyl group, an isopropenyl group, a butenyl group, an isobutenyl group, a tert-butenyl group, a pentenyl group, a hexenyl group, a heptenyl group, an octenyl group, an isooctenyl group, a nonenyl group and the like.

Examples of the alkynyl group having 2 to 12 carbon atoms include an ethynyl group, a propynyl group, an isopropynyl group, a butynyl group, an isobutynyl group, a tert-butynyl group, a pentynyl group, a hexynyl group, an octynyl group, a nonynyl group and the like.

Examples of the alkoxy group having 1 to 8 carbon atoms represented by R^{b2} include a methoxy group, an ethoxy group, a propoxy group, a butoxy group, a pentyloxy group and the like.

Examples of the thioalkyl group having 1 to 8 carbon atoms represented by R^{b2} include a thiomethyl group, a thioethyl group, a thiopropyl group, a thiobutyl group, a thiopentyl group and the like.

Examples of the aromatic hydrocarbon ring having 6 to 14 carbon atoms represented by ring W^{b1} include a benzene ring, a naphthalene ring, an anthracene ring and the like.

Examples of the aromatic heterocyclic ring having 6 to 14 carbon atoms represented by ring W^{b1} include rings in which the numbers of atoms constituting the ring is 6 to 14, and the following rings are preferable.

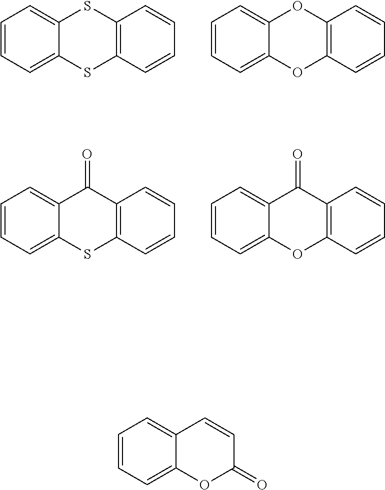

The ring W^{b1} is preferably a naphthalene ring.

The compound represented by formula (b1) is preferably a compound represented by any one of formula (b4) to formula (b7), and more preferably a compound represented by formula (b4):

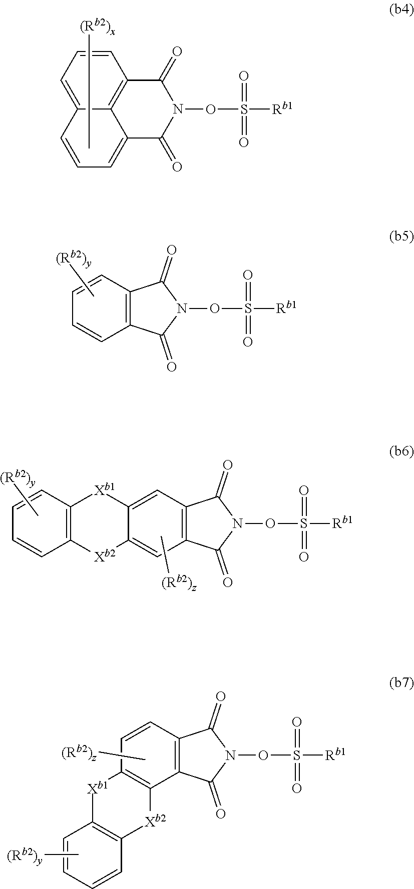

wherein, in formula (b4) to formula (b7),
R^{b1}, R^{b2} and x are the same as defined above,
y represents an integer of 0 to 4, and z represents an integer of 0 to 2,
X^{b1} and X^{b}2 each independently represent —O—, —S— or —CO—, and
when including a plurality of R^{b2}, a plurality of R^{b2} may be the same or different from each other.

Examples of the compound represented by formula (b1) include compounds represented by formula (b1-1) to formula (b1-24). Compounds represented by formula (b1-6), formula (b1-7), formula (b1-13), formula (b1-14), formula (b1-17), formula (b1-18) and formula (b1-24) are preferable.

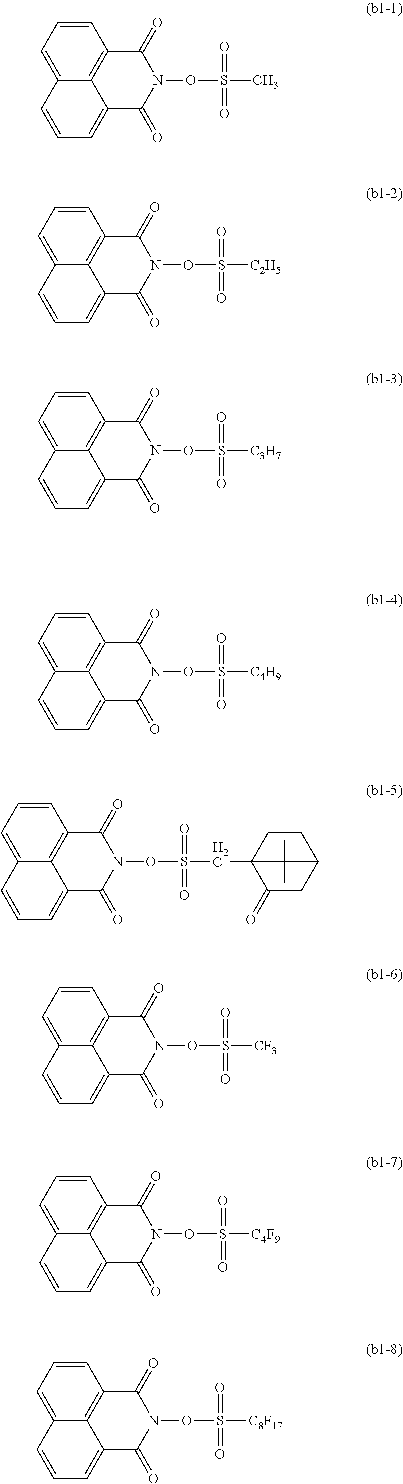

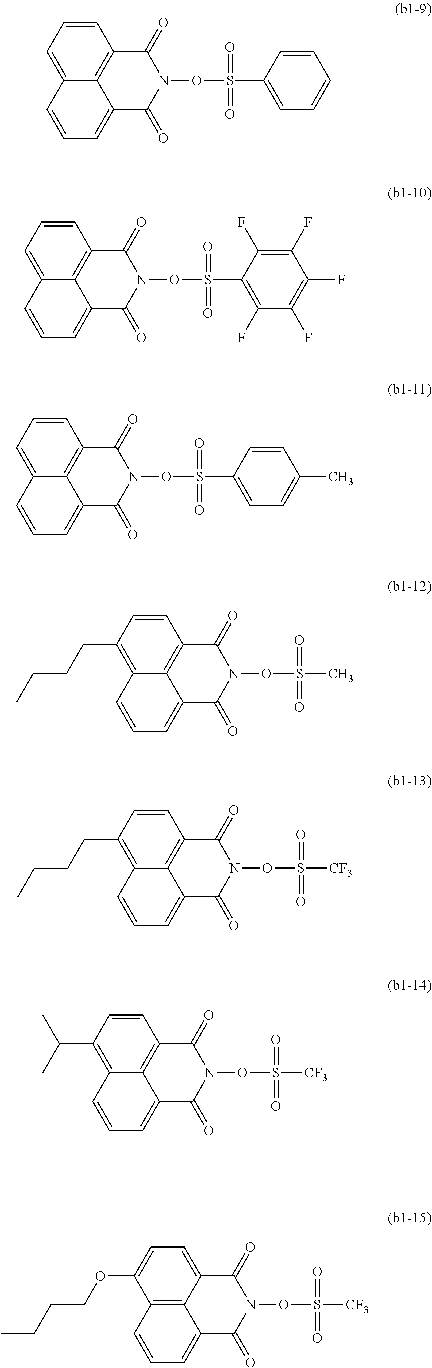

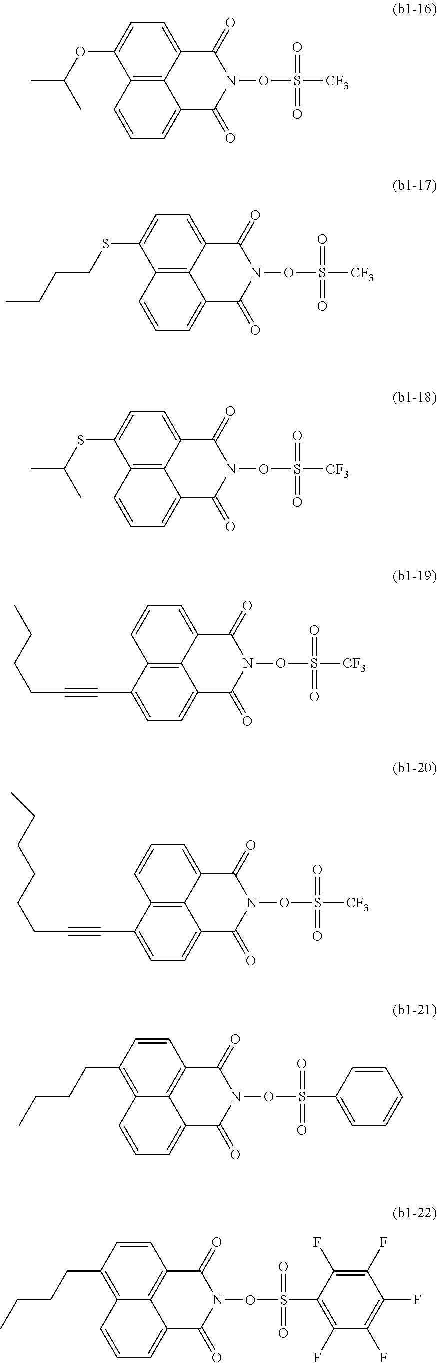

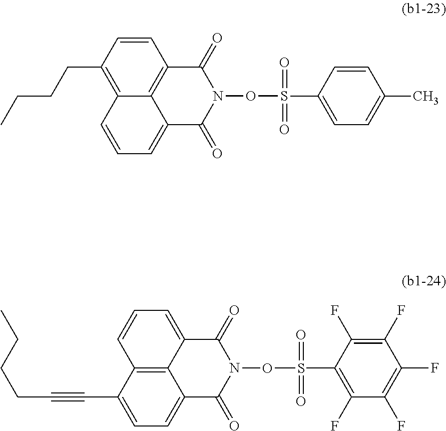 [SMILES: CCCCc1ccc2c3c(cccc13)C(=O)N(OS(=O)(=O)c1ccc(C)cc1)C2=O ; CCCCC#Cc1ccc2c3c(cccc13)C(=O)N(OS(=O)(=O)c1c(F)c(F)c(F)c(F)c1F)C2=O]

Examples of the compound having a group represented by formula (B1), which is contained in the acid generator (B), also include compounds other than the compound represented by formula (b1). Examples of the compound include a compound represented by formula (b2), a compound represented by formula (b3) and the like:

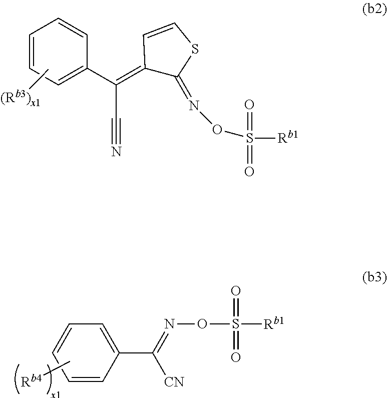

wherein, in formula (b2) and formula (b3),
R^{b1} is the same as defined above,
R^{b3} and R^{b4} each independently represent a hydrocarbon group having 1 to 12 carbon atoms, an alkoxy group having 1 to 8 carbon atoms or a thioalkyl group having 1 to 8 carbon atoms, and
x1 represents an integer of 0 to 5, and when x1 is 2 or more, a plurality of R^{b3} or R^{b4} may be the same or different.

Examples of the hydrocarbon group having 1 to 12 carbon atoms represented by R^{b3} and R^{b4} are, independently of each other, the same as the hydrocarbon group having 1 to 12 carbon atoms represented by R^{b2}.

Examples of the alkoxy group having 1 to 8 carbon atoms represented by R^{b3} and R^{b4} are, independently of each other, the same as the alkoxy group having 1 to 8 carbon atoms represented by R^{b2}.

Examples of the thioalkyl group having 1 to 8 carbon atoms represented by R^{b3} and R^{b4} are, independently of each other, the same as the thioalkyl group having 1 to 8 carbon atoms represented by R^{b2}.

Examples of the compound represented by formula (b2) include compounds represented by the following formulas and the like.

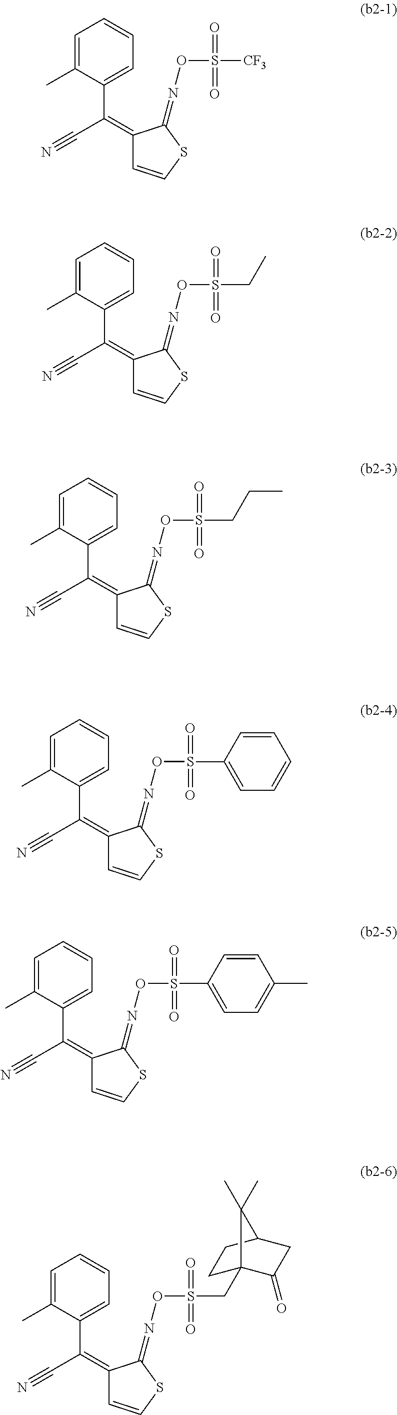

Examples of the compound represented by formula (b3) include compounds represented by the following formulas and the like.

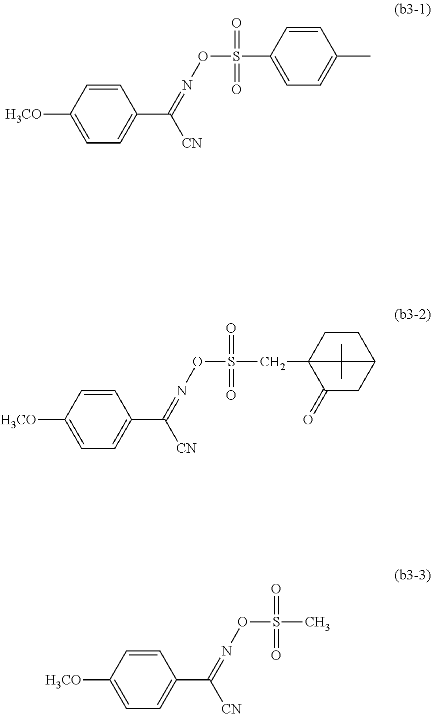 [SMILES: COc1ccc(C(C#N)=NOS(=O)(=O)c2ccc(C)cc2)cc1 ; COc1ccc(C(C#N)=NOS(=O)(=O)CC23CCC(CC2=O)C3(C)C)cc1 ; COc1ccc(C(C#N)=NOS(C)(=O)=O)cc1]

At least one selected from the compounds represented by formula (b1) contained in the acid generator (B) is preferably a compound in which x is 1. Of these, the compound is preferably a compound in which R^{b2} is a hydrocarbon group having 1 to 8 carbon atoms, more preferably a compound in which R^{b2} is an alkyl group having 1 to 8 carbon atoms, an alkenyl group having 2 to 8 carbon atoms or an alkynyl group having 2 to 8 carbon atoms, still more preferably a compound in which R^{b2} is an alkyl group having 1 to 8 carbon atoms or an alkynyl group having 2 to 8 carbon atoms, and yet more preferably a compound in which R^{b2} is an alkyl group having 1 to 8 carbon atoms.

The acid generator (B) used in the present invention preferably contains a compound having a group represented by formula (B1) as mentioned above, and more preferably contains at least one of a compound represented by formula (b1).

When the acid generator (B) contains two or more types of compounds having a group represented by formula (B1), preferred examples thereof include those containing the following combinations:
(i) combinations of at least two compounds selected from the compounds represented by formula (b1), or
(ii) combinations of at least one compound selected from the compounds represented by formula (b1) and at least one compound selected from the compounds represented by formula (b2) and formula (b3).

Of the above combinations of (i) mentioned above, preferred examples thereof include combinations of at least one compound selected from the compounds represented by formula (b1) (wherein x is 1, and R^{b1}, R^{b2} and W^{b1} are the same as defined above) and at least one compound selected from the compounds represented by formula (b1) (wherein x is 0, and R^{b1} and W^{b1} are the same as defined above).

Of the combinations of (i) mentioned above, other preferred examples thereof include combinations of at least two compounds selected from the compounds represented by formulas (b4) to (b7).

Of the combinations of (i) mentioned above, other preferred examples thereof include combinations of at least two compounds selected from the compounds represented by formula (b4).

Of the combinations of (i) mentioned above, other preferred examples thereof include combinations of at least one compound selected from the compounds represented by formula (b4) (wherein x is 0, and R^{b1} and R^{b2} are the same as defined above) and at least one compound selected from the compounds represented by formula (b4) (wherein x is 1, and R^{b1} and R^{b2} are the same as defined above).

Of the combinations of (i) mentioned above, other preferred examples thereof include combinations of at least one compound selected from the compounds represented by formulas (b1-1) to (b1-11) and at least one compound selected from the compounds represented by formulas (b1-12) to (b1-20).

Of the combinations of (ii) mentioned above, preferred examples thereof include combinations of at least one compound selected from the compounds represented by formula (b4), and at least one compound selected from the compounds represented by formulas (b2) and (b3).

Of the combinations of (ii) mentioned above, other preferred examples thereof include combinations of at least one compound selected from the compounds represented by formula (b4) and at least one compound selected from the compounds represented by formula (b2).

Of the combinations of (ii) mentioned above, other preferred examples thereof include combinations of at least one compound selected from the compounds represented by formula (b1-1) to formula (b1-20) and at least one compound selected from the compounds represented by formula (b2-1) to formula (b2-6) and formula (b3-1) to formula (b3-3).

Of the combinations of (ii) mentioned above, other preferred examples thereof include combinations of at least one compound selected from the compounds represented by formula (b1-1) to formula (b1-11) and at least one compound selected from the compounds represented by formula (b2-1) to formula (b2-6).

The ionic acid generator is preferably a compound represented by formula (b8) or formula (b9):

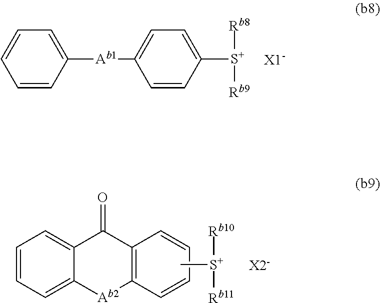

wherein, in formula (b8) or formula (b9),
A^{b1} and A^{b2} each independently represent an oxygen atom or a sulfur atom,
R^{b8}, R^{b9}, R^{b10} and R^{b11} each independently represent an alkyl group having 1 to 10 carbon atoms or an aromatic hydrocarbon group having 6 to 12 carbon atoms, and
X1⁻ and X2⁻ represent an organic anion.

Examples of the alkyl group having 1 to 10 carbon atoms include a methyl group, an ethyl group, a propyl group, a butyl group, a pentyl group, a hexyl group, a heptyl group, an octyl group and the like.

Examples of the aromatic hydrocarbon group having 6 to 12 carbon atoms include aryl groups such as a phenyl group, a naphthyl group, an anthryl group, a biphenyl group and a phenanthryl group. The aromatic hydrocarbon group may further have a substituent and the aromatic hydrocarbon group having a substituent is, for example, an aromatic hydrocarbon group having an aralkyl group or an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, a 2-methyl-6-ethylphenyl group and the like.

R^{b8}, R^{b9}, R^{b10} and R^{b11} are each preferably an aromatic hydrocarbon group having 6 to 12 carbon atoms, and more preferably a phenyl group.

Examples of the organic anion represented by X1⁻ and X2⁻ include a sulfonic acid anion, a bis(alkylsulfonyl)amide anion, a tris(alkylsulfonyl)methide anion and the like, of which a sulfonic acid anion is preferable, and a sulfonic acid anion represented by formula (b10) is more preferable:

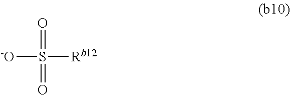

wherein, in formula (b10),
R^{b12} represents a hydrocarbon group having 1 to 18 carbon atoms which may have a fluorine atom, and a methylene group included in the hydrocarbon group may be replaced by an oxygen atom or a carbonyl group.

Examples of R^{b12} include the same groups as for R^{b1} in formula (B1).

Examples of the compound represented by formula (b8) include the following compounds and the like.

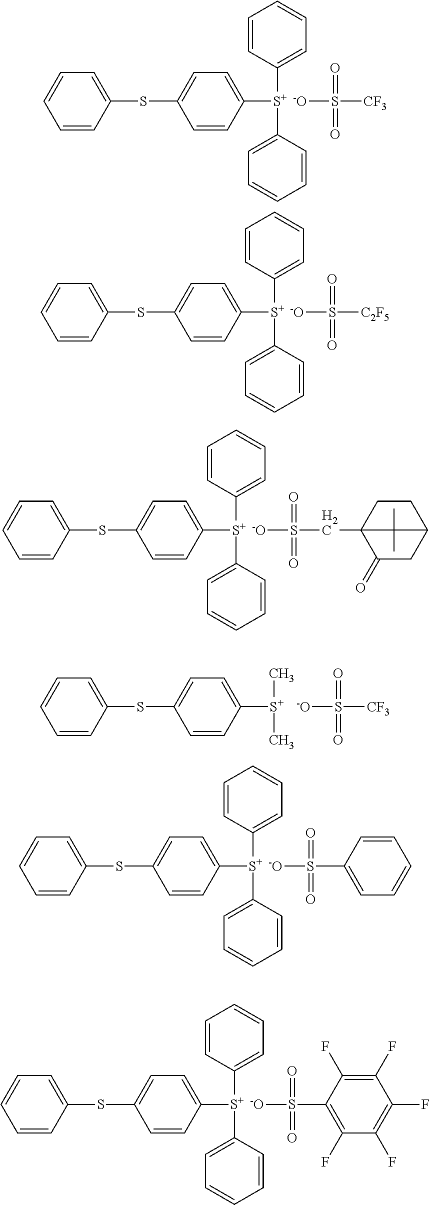

Examples of the compound represented by formula (b9) include the following compounds and the like.

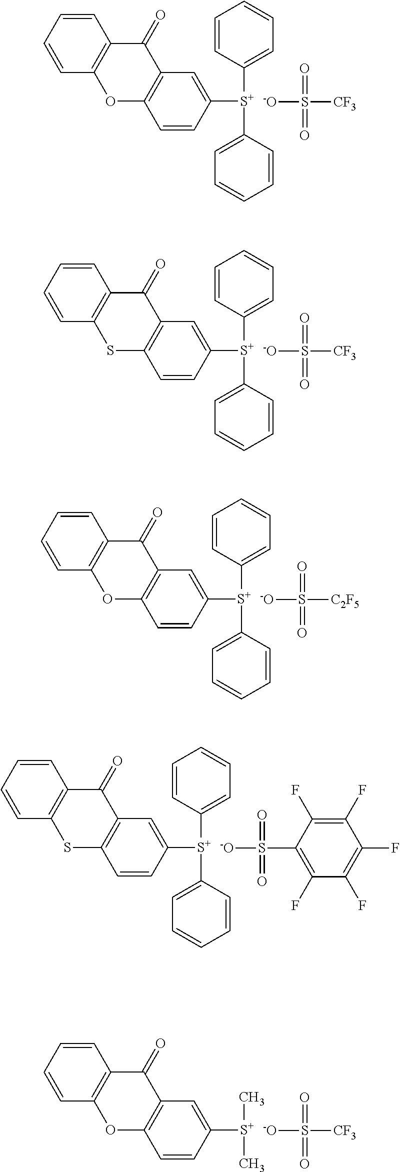

The total content of the acid generator (B) in the negative resist composition of the present invention is preferably 0.1 part by mass or more and 40 parts by mass or less, more preferably 0.5 part by mass or more and 30 parts by mass or less, still more preferably 1 part by mass or more and 20 parts by mass or less, and yet more preferably 1 part by mass or more and 5 parts by mass or less, based on 100 parts by mass of the total amount of the resin.

### <Crosslinking Agent (E)>

The crosslinking agent (E) is a compound which is bonded to the resin (A1) by the action of an acid generated when the acid generator (B) is decomposed by light irradiation (exposure). A crosslinked structure is formed by bonding with the resin.

Examples of the crosslinking agent include melamine-based crosslinking agents, urea-based crosslinking agents, alkyleneurea-based crosslinking agent and glycoluril-based crosslinking agents.

Examples of the melamine-based crosslinking agent include a compound represented by formula (e1):

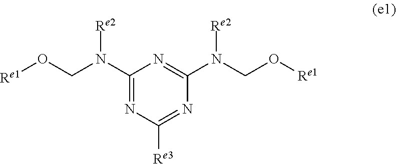

wherein, in formula (e1),
R^{e1} each independently represent a hydrogen atom, or a hydrocarbon group having 1 to 6 carbon atoms,
R^{e2} each independently represent a hydrogen atom, a hydrocarbon group having 1 to 6 carbon atoms, or —CH₂—O—R^{e1}, and
R^{e3} represents a hydrogen atom, a hydrocarbon group having 1 to 6 carbon atoms, or a group represented by formula (e1-1), and:

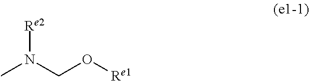

wherein, in formula (e1-1), R^{e1} and R^{e2} represent the same group as in formula (e1).

Specific examples of the melamine-based crosslinking agent include N,N,N,N,N,N-hexakis(methoxymethyl)melamine, N,N,N,N,N,N-hexakis(ethoxymethyl)melamine, N,N,N,N,N,N-hexakis(propoxymethyl)melamine, N,N,N,N,N,N-hexakis(isopropoxymethyl)melamine, N,N,N,N,N,N-hexakis(butoxymethyl)melamine, N,N,N,N,N,N-hexakis(t-butoxymethyl)melamine, N,N,N,N,N,N-hexakis(cyclohexyloxymethyl)melamine, N,N,N,N,N,N-hexakis(cyclopentyloxymethyl)melamine, N,N,N,N,N,N-hexakis(adamantyloxymethyl)melamine, N,N,N,N,N,N-hexakis(norbornyloxymethyl)melamine, N,N,N,N,-tetrakis(methoxymethyl)acetoguanamine, N,N,N,N-tetrakis(ethoxymethyl)acetoguanamine, N,N,N,N-tetrakis(propoxymethyl)acetoguanamine, N,N,N,N-tetrakis(isopropoxymethyl)acetoguanamine, N,N,N,N-tetrakis(butoxymethyl)acetoguanamine, N,N,N,N-tetrakis(t-butoxymethyl) acetoguanamine, N,N,N,N-tetrakis(methoxymethyl)benzoguanamine, N,N,N,N-tetrakis(ethoxymethyl)benzoguanamine, N,N,N,N-tetrakis(propoxymethyl)benzoguanamine, N,N,N,N-tetrakis(isopropoxymethyl)benzoguanamine, N,N,N,N-tetrakis(butoxymethyl)benzoguanamine, N,N,N,N-tetrakis(t-butoxymethyl)benzoguanamine and the like.

Examples of the urea-based crosslinking agent include a compound represented by formula (e2):

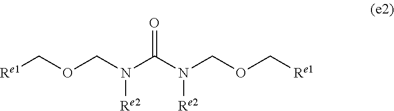

wherein, in formula (e2), R^{e1} and R^{e2} represent the same group as in formula (e1).

Specific examples of the urea-based crosslinking agent include N,N-di(methoxymethyl)urea, N,N-di(ethoxymethyl)urea, N,N-di(propoxymethyl)urea, N,N-di(isopropoxymethyl)urea, N,N-di(butoxymethyl) urea, N, N-di(t-butoxymethyl) urea, N, N-di(cyclohexyloxymethyl)urea, N,N-di(cyclopentyloxymethyl)urea, N,N-di(adamantyloxymethyl)urea and N,N-di(norbornyloxymethyl)urea.

Examples of the alkyleneurea-based crosslinking agent include a compound represented by formula (e3):

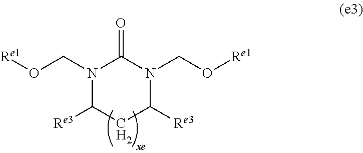

wherein, in formula (e3),
R^{e1} represents the same group as in formula (e1), and
R^{e3} each independently represent a hydrogen atom, a hydroxyl group, a hydrocarbon group having 1 to 6 carbon atoms or an alkoxy group having 1 to 6 carbon atoms, and xe represents an integer of 0 to 2.

Specific examples of the alkyleneurea-based crosslinking agent include N,N-di(methoxymethyl)-4,5-di(methoxymethyl)ethyleneurea, N,N-di(ethoxymethyl)-4,5-di(ethoxymethyl)ethyleneurea, N,N-di(propoxymethyl)-4,5-di(propoxymethyl)ethyleneurea, N,N-di(isopropoxymethyl)-4,5-di(isopropoxymethyl)ethyleneurea, N,N-di(butoxymethyl)-4,5-di(butoxymethyl)ethyleneurea, N, N-di(t-butoxymethyl)-4,5-di(t-butoxymethyl)ethyleneurea, N, N-di(cyclohexyloxymethyl)-4,5-di(cyclohexyloxymethyl)ethyleneurea, N,N-di(cyclopentyloxymethyl)-4,5-di(cyclopentyloxymethyl)ethyleneurea, N,N-di(adamantyloxymethyl)-4,5-di(adamantyloxymethyl)ethyleneurea, N,N-di(norbornyloxymethyl)-4,5-di(norbornyloxymethyl)ethyleneurea and the like.

Examples of the glycoluril-based crosslinking agent include formula (e4):

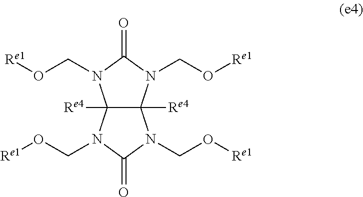

wherein, in formula (e4),
R^{e1} represents the same group as in formula (e1), and
R^{e4} each independently represent a hydrogen atom, a hydroxyl group, a hydrocarbon group having 1 to 6 carbon atoms or an alkoxy group having 1 to 6 carbon atoms.

Specific examples of the glycoluril-based crosslinking agent include N,N,N,N-tetra(methoxymethyl)glycoluril, N,N,N,N-tetra(ethoxymethyl)glycoluril, N,N,N,N-tetra(propoxymethyl)glycoluril, N,N,N,N-tetra(isopropoxymethyl)glycoluril, N,N,N,N-tetra(butoxymethyl)glycoluril, N,N,N,N-tetra(t-butoxymethyl)glycoluril, N,N,N,N-tetra(cyclohexyloxymethyl)glycoluril, N,N,N,N-tetra(cyclopentyloxymethyl)glycoluril, N,N,N,N-tetra(adamantyloxymethyl)glycoluril, N,N,N,N-tetra(norbornyloxymethyl)glycoluril and the like.

Of the above, the crosslinking agent (E) is preferably a melamine-based crosslinking agent or a glycoluril-based crosslinking agent. The crosslinking agent (E) may be used alone, or two or more thereof may be used in combination.

In the negative resist composition of the present inventio, the content of the crosslinking agent (E) is preferably 1 to 50 parts by mass, more preferably 2 to 40 parts by mass, and still more preferably 3 to 30 parts by mass, based on 100 parts by mass of the total amount of the resin.

### <Solvent (D)>

The content of the solvent (D) in the negative resist composition is usually 45% by mass or more, preferably 50% by mass or more, and more preferably 55% by mass or more, and is usually 99.9% by mass or less, preferably 99% by mass or less, and more preferably 90% by mass or less. The content of the solvent (D) can be measured, for example, by known analytical means such as liquid chromatography or gas chromatography.

Examples of the solvent (D) include glycol ether esters such as ethylcellosolve acetate, methylcellosolve acetate and propylene glycol monomethyl ether acetate; glycol ethers such as propylene glycol monomethyl ether; esters such as ethyl lactate, butyl acetate, amyl acetate and ethyl pyruvate; ketones such as acetone, methyl isobutyl ketone, 2-heptanone and cyclohexanone; and cyclic esters such as γ-butyrolactone.

The solvents (D) may be included alone, or two or more thereof may be included.

### <Quencher (C)>

The negative resist composition of the present invention may include a quencher (hereinafter sometimes referred to as “quencher (C)”).

The quencher (C) is a compound having the action of trapping an acid generated from an acid generator upon exposure. Examples of the quencher (C) include a basic nitrogen-containing organic compound. Examples of the basic nitrogen-containing organic compound include amine and an ammonium salt. Examples of the amine include an aliphatic amine (including primary amine, secondary amine and tertiary amine), an aromatic amine and the like.

Examples of the amine include a compound represented by formula (C1) or formula (C2):

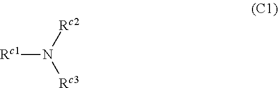

wherein, in formula (C1), R^{c1}, R^{c2} and R^{c3} each independently represent a hydrogen atom, an alkyl group having 1 to 6 carbon atoms, an alicyclic hydrocarbon group having 3 to 10 carbon atoms or an aromatic hydrocarbon group having 6 to 10 carbon atoms, and the alkyl group having 1 to 6 carbon atoms and the alicyclic hydrocarbon group having 3 to 10 carbon atoms may have at least one selected from the group consisting of a hydroxy group, an amino group and an alkoxy group having 1 to 6 carbon atoms, and the aromatic hydrocarbon group having 6 to 10 carbon atoms may have at least one selected from the group consisting of an alkyl group having 1 to 6 carbon atoms, an alkoxy group having 1 to 6 carbon atoms and an alicyclic hydrocarbon group having 3 to 10 carbon atoms.

Examples of the alkyl group having 1 to 6 carbon atoms and the alkoxy group having 1 to 6 carbon atoms in formula (C1) include the same as those mentioned above.

Examples of the alicyclic hydrocarbon group having 3 to 10 carbon atoms include monocyclic alicyclic hydrocarbon groups, for example, cycloalkyl groups such as a cyclopentyl group, a cyclohexyl group, a cycloheptyl group and a cyclooctyl group; and polycyclic alicyclic hydrocarbon groups such as a decahydronaphthyl group, an adamantyl group and a norbornyl group.

Examples of the aromatic hydrocarbon group having 6 to 10 carbon atoms include aryl groups such as a phenyl group and a naphthyl group. The aromatic hydrocarbon group may further have a substituent, and examples of the substituent include an aryloxy group having 6 to 10 carbon atoms.

Examples of the compound represented by formula (C1) include 1-naphthylamine, 2-naphthylamine, aniline, diisopropylaniline, 2-, 3- or 4-methylaniline, 4-nitroaniline, N-methylaniline, N,N-dimethylaniline, diphenylamine, hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, dibutylmethylamine, methyldipentylamine, dihexylmethylamine, dicyclohexylmethylamine, diheptylmethylamine, methyldioctylamine, methyldinonylamine, didecylmethylamine, ethyldibutylamine, ethyldipentylamine, ethyldihexylamine, ethyldiheptylamine, ethyldioctylamine, ethyldinonylamine, ethyldidecylamine, tris[2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylmethane and the like. Diisopropylaniline is preferable, and 2,6-diisopropylaniline is particularly preferable:

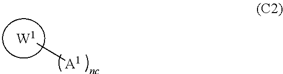

wherein, in formula (C2),
ring W¹ represents a heterocyclic ring having a nitrogen atom in atoms constituting the ring, or a benzene ring having a substituted or unsubstituted amino group, and the heterocyclic ring and the benzene ring may have at least one selected from the group consisting of a hydroxy group and an alkyl group having 1 to 4 carbon atoms,
A¹ represents a phenyl group or a naphthyl group, and
nc represents 2 or 3, and a plurality of A1 may be the same or different.

The substituted or unsubstituted amino group is represented by —N(R⁴)(R⁵), R⁴ and R⁵ each independently represent a hydrogen atom, a chain hydrocarbon group having 1 to 10 carbon atoms, an alicyclic hydrocarbon group having 3 to 10 carbon atoms, or an aromatic hydrocarbon group having 6 to 14 carbon atoms.

Examples of the chain hydrocarbon group having 1 to 10 carbon atoms include alkyl groups having 1 to 10 carbon atoms such as a methyl group, an ethyl group, a propyl group, a butyl group, a pentyl group, a hexyl group, a heptyl group and an octyl group.

Examples of the alicyclic hydrocarbon group having 3 to 10 carbon atoms include monocyclic alicyclic hydrocarbon groups, for example, cycloalkyl groups such as a cyclopentyl group, a cyclohexyl group, a cycloheptyl group and a cyclooctyl group; and polycyclic alicyclic hydrocarbon groups such as a decahydronaphthyl group, an adamantyl group and a norbornyl group.

Examples of the aromatic hydrocarbon group having 6 to 14 carbon atoms include aryl groups such as a phenyl group, a naphthyl group, an anthryl group, a biphenyl group and a phenanthryl group. The aromatic hydrocarbon group may further have a substituent, and examples of the substituent include an aryloxy group having 6 to 10 carbon atoms.

The heterocyclic ring having a nitrogen atom in atoms constituting the ring may be either an aromatic ring or a nonaromatic ring, and may have other heteroatoms (e.g., oxygen atom, sulfur atom) together with the nitrogen atom. The number of nitrogen atoms possessed by the heterocyclic ring is, for example, 1 to 3. Examples of the heterocyclic ring include a ring represented by any one of formula (Y13) to formula (Y28). One hydrogen atom included in the ring is eliminated to form a bond with A¹.

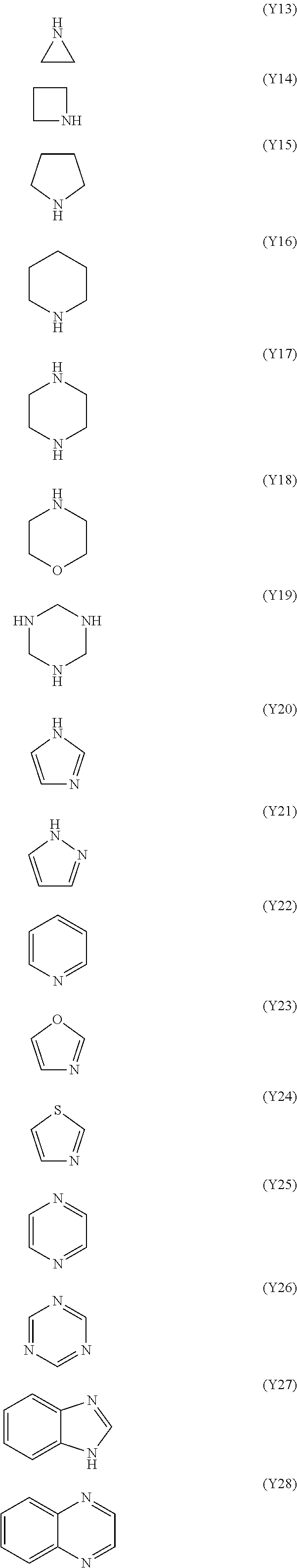

The ring W¹ is preferably a heterocyclic ring having a nitrogen atom in atoms constituting the ring, more preferably a 5- or 6-membered aromatic heterocyclic ring having a nitrogen atom in atoms constituting the ring, and still more preferably a ring represented by any one of formula (Y20) to formula (Y25).

Examples of the compound represented by formula (C2) include a compound represented by any one of formula (C2-1) to formula (C2-11). A compound represented by any one of formula (C2-2) to formula (C2-8) is preferable.

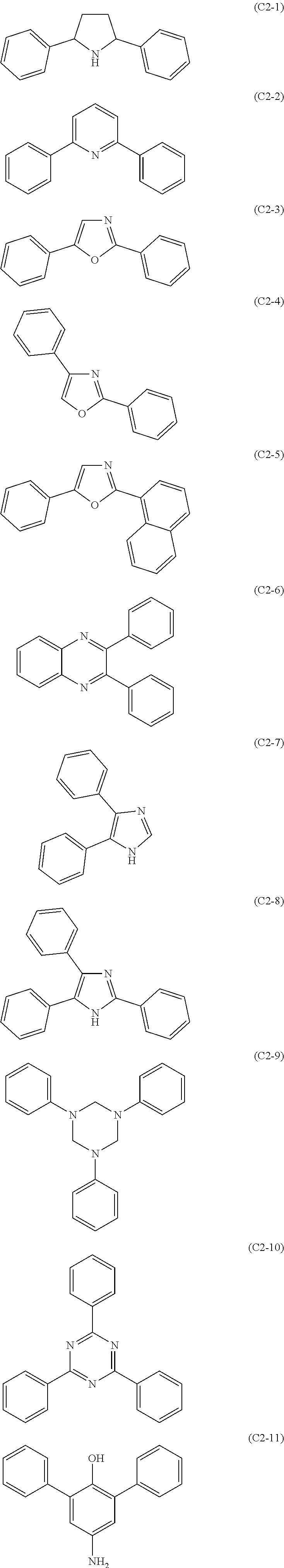

The content of the quencher (C) in the solid content of the negative resist composition is preferably 0.0001 to 5% by mass, more preferably 0.0001 to 4% by mass, still more preferably 0.001 to 3% by mass, yet more preferably 0.01 to 1.0% by mass, and further preferably 0.1 to 0.7% by mass.

### <Other Components (F)>

The negative resist composition according to the present invention may also include components other than the components mentioned above (hereinafter sometimes referred to as “other components (F)”), if necessary. The other components (F) are not particularly limited and it is possible to use various additives known in the resist field, for example, sensitizers, dissolution inhibitors, surfactants, stabilizers, dyes, adhesion improves and the like.

When the other components (F) are used, the content is appropriately selected according to the type of the other components (F).

### 2. Preparation of Negative Resist Composition

The negative resist composition according to the present invention can be prepared by mixing a resin (A1), a novolak resin (A2), a resin (A3), a crosslinking agent (E) and an acid generator (B), and if necessary, resins other than the resins (A1) to (A3), a quencher (C), a solvent (D) and other components (F). The order of mixing these components is any order and is not particularly limited. Examples of the temperature during mixing include 10 to 40° C., and it is possible to select appropriate temperature according to the type of the resin, the solubility in the solvent (D) of the resin and the like. It is possible to select, as the mixing time, appropriate time from 0.5 to 24 hours according to the mixing temperature. The mixing means is not particularly limited and it is possible to use mixing with stirring.

After mixing the respective components, the mixture is preferably filtered through a filter having a pore diameter of about 0.003 to 50 μm.

### 3. Method for Producing Resist Pattern

The method for producing a resist pattern according to the present invention includes:
(1) a step of applying the negative resist composition of the present invention on a substrate,
(2) a step of drying the applied negative resist composition to form a composition layer,
(3) a step of exposing the composition layer, and
(4) a step of heating and developing the exposed composition layer.

The negative resist composition can be usually applied on a substrate using a conventionally used apparatus, such as a spin coater. Examples of the substrate include inorganic substrates such as a silicon wafer. On the substrate, a semiconductor device (e.g., transistor, diode, etc.) may be formed in advance.

The solvent is removed by drying the applied composition to form a composition layer. Drying is performed by evaporating the solvent using a heating device such as a hot plate (so-called “prebake”), or a decompression device. The heating temperature is preferably 50 to 200° C. and the heating time is preferably 30 to 600 seconds. The pressure during drying under reduced pressure is preferably about 1 to 1.0×10⁵ Pa.

The film thickness of the composition obtained after drying is preferably 1 to 50 μm, and more preferably 1.5 to 30 μm.

The composition layer thus obtained is usually exposed using an aligner. It is possible to use, as an exposure source, various exposure sources, for example, light sources capable of emitting light having a wavelength of 345 to 436 nm (g-ray (wavelength: 436 nm), h-ray (wavelength: 405 nm), i-ray (wavelength: 365 nm), exposure sources capable of emitting laser beam in an ultraviolet region such as KrF excimer laser (wavelength of 248 nm), ArF excimer laser (wavelength of 193 nm) and F₂ excimer laser (wavelength of 157 nm), an exposure source capable of emitting harmonic laser beam in a far-ultraviolet or vacuum ultra violet region by wavelength-converting laser beam from a solid-state laser source (YAG or semiconductor laser), an exposure source capable of emitting electron beam or extreme ultraviolet light (EUV) and the like. Of these, preferred are those in which i-ray is used as the exposure source.

In the present specification, such exposure to radiation is sometimes collectively referred to as “exposure”. The exposure is usually performed through a mask corresponding to a pattern to be required. When electron beam is used as the exposure source, exposure may be performed by direct writing without using the mask.

The exposed composition layer may be subjected to a heat treatment (so-called “post-exposure bake”) to promote a crosslinking reaction between the resin and the crosslinking agent. The heating temperature is usually about 50 to 200° C., and preferably about 70 to 150° C. The heating time is usually 40 to 400 seconds, and preferably 50 to 350 seconds.

The heated composition layer is usually developed with a developer using a development apparatus. Examples of the developing method include a dipping method, a paddle method, a spraying method, a dynamic dispensing method and the like. The developing temperature is preferably, for example, 5 to 60° C. and the developing time is preferably, for example, 5 to 600 seconds.

In the negative resist composition of the present invention, an alkaline developer is used as the developer. The alkaline developer may be various aqueous alkaline solutions used in this field. Examples thereof include aqueous solutions of tetramethylammonium hydroxide and (2-hydroxyethyl)trimethylammonium hydroxide (commonly known as choline). The surfactant may be contained in the alkaline developer.

It is preferable that the developed resist pattern is washed with ultrapure water and then water remaining on the substrate and the pattern is removed.

After washing, the rinsing solution remaining on the substrate and the pattern is preferably removed.

It is possible to form a resist pattern having a shape with high accuracy by exposing a resist obtained by using the negative resist composition of the present invention.

### 4. Applications

The negative resist composition of the present invention is useful for the production of a thick resist film. For example, it is useful for the production of a resist film having a film thickness of 1 to 50 μm (more preferably film thickness of 1.5 to 30 μm).

### EXAMPLES

The present invention will be described more specifically by way of Examples. Percentages and parts expressing the contents or amounts used in the Examples are by mass unless otherwise specified.

The weight-average molecular weight is a value determined by gel permeation chromatography under the following conditions.
Apparatus: Model HLC-8320GPC (manufactured by TOSOH CORPORATION)
Column: TSKgel Multipore H_{XL}-M×3+guardcolumn (manufactured by TOSOH CORPORATION)
Eluent: tetrahydrofuran
Flow rate: 1.0 mL/min
Detector: RI detector
Column temperature: 40° C.
Injection amount: 100 μl
Molecular weight standard: standard polystyrene (manufactured by TOSOH CORPORATION)

### Synthesis Example 1 [Synthesis of Resin (A2)-3]

In a four-necked flask equipped with a stirrer, a reflux condenser and a thermometer, 413.5 parts of 2,5-xylenol, 103.4 parts of salicylaldehyde, 20.1 parts of p-toluenesulfonic acid and 826.9 parts of methanol were added, followed by heating to reflux and further warm-keeping for 4 hours. After cooling, 1,320 parts of methyl isobutyl ketone was added and 1,075 parts of the solvent was distilled off under normal pressure. 762.7 Parts of m-cresol and 29.0 parts of 2-tert-butyl-5-methylphenol were added thereto, and after raising the temperature to 65° C., 678 parts of 37% formalin was added dropwise over 1.5 hours while adjusting the temperature so that the temperature reaches 87° C. after completion of the dropwise addition. The mixture thus obtained was kept warm at 87° C. for 10 hours and 1,115 parts of methyl isobutyl ketone was added, followed by washing through separation with ion-exchanged water three times. To the mixture thus obtained, 500 parts of methyl isobutyl ketone was added, followed by concentration under reduced pressure until the total amount became 3,435 parts. To the mixture thus obtained, 3,796 parts of methyl isobutyl ketone and 4,990 parts of n-heptane were added, followed by raising the temperature to 60° C. and further stirring for 1 hour. Thereafter, the under layer containing the resin was isolated through separation, followed by dilution with 3,500 parts of propylene glycol monomethyl ether acetate and further concentration to obtain 1,690 parts (solid content of 43%) of a propylene glycol monomethyl ether acetate solution of a resin (A2)-3. The weight-average molecular weight of the novolak resin (A2)-3 was 7×10³.

### Synthesis Example 2 [Synthesis of Resin (A3)-1]

In a four-necked flask equipped with a stirrer, a reflux condenser and a thermometer, 70 parts of ethyl acetate was added, and after temperature rise to 80° C., a mixture of 20 parts of methacrylic acid, 58 parts of ethyl acrylate, 35 parts of methyl methacrylate (molar ratio of methacrylic acid:ethyl acrylate:methyl methacrylate=20:50:30), 4.91 parts of 2,2′-azobis(2-methylbutyronitrile) and 100 parts of ethyl acetate was added dropwise over 2 hours. The mixture was stirred for 3 hours while maintaining at 80° C. to 85° C. The reaction mixture thus obtained was cooled to 40° C. or lower and diluted with 125 parts of ethyl acetate, and then a large amount of a mixed solution of ion-exchanged water and methanol to precipitate a resin, followed by filtration and recovery. To the resin thus obtained, 650 parts of propylene glycol monomethyl ether acetate was added, and after dissolution and concentration, 650 parts of propylene glycol monomethyl ether acetate was added and the mixture was concentrated again to obtain 185 parts of a propylene glycol monomethyl ether acetate solution of a resin (A3)-1 (solid content of 49%, yield of 80%). The weight-average molecular weight of the resin (A3)-1 was 1.26×10⁴.

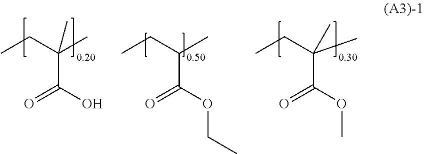

### Synthesis Example 3 [Synthesis of Resin (A3)-2]

In a four-necked flask equipped with a stirrer, a reflux condenser and a thermometer, 70 parts of ethyl acetate was added, and after temperature rise to 80° C., a mixture of 20 parts of methacrylic acid, 58 parts of ethyl acrylate, 35 parts of methyl methacrylate (molar ratio of methacrylic acid:ethyl acrylate:methyl methacrylate=20:50:30), 6.03 parts of 2,2′-azobis(2-methylbutyronitrile) and 100 parts of ethyl acetate was added dropwise over 2 hours. The mixture was stirred for 3 hours while maintaining at 80° C. to 85° C. The reaction mixture thus obtained was cooled to 40° C. or lower and diluted with 125 parts of ethyl acetate, and then a large amount of a mixed solution of ion-exchanged water and methanol to precipitate a resin, followed by filtration and recovery. To the resin thus obtained, 650 parts of propylene glycol monomethyl ether acetate was added, and after dissolution and concentration, 650 parts of propylene glycol monomethyl ether acetate was added and the mixture was concentrated again to obtain 190 parts of a propylene glycol monomethyl ether acetate solution of a resin (A3)-2 (solid content of 48%, yield of 81%). The weight-average molecular weight of the resin (A3)-2 was 9.94×10³.

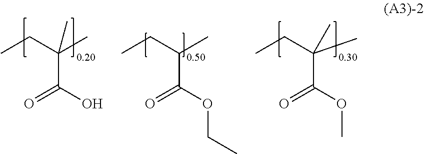

### Synthesis Example 4 [Synthesis of Resin (A3)-3]

In a four-necked flask equipped with a stirrer, a reflux condenser and a thermometer, 70 parts of ethyl acetate was added, and after temperature rise to 55° C., a mixture of 15 parts of methacrylic acid, 58 parts of ethyl acrylate, 41 parts of methyl methacrylate (molar ratio of methacrylic acid:ethyl acrylate:methyl methacrylate=15:50:35), 3.46 parts of 2,2′-azobis(2,4-dimethylvaleronitrile) and 100 parts of ethyl acetate was added dropwise over 2 hours. The mixture was stirred for 3 hours while maintaining at 50° C. to 55° C. The reaction mixture thus obtained was cooled to 40° C. or lower and diluted with 125 parts of ethyl acetate, and then a large amount of a mixed solution of ion-exchanged water and methanol to precipitate a resin, followed by filtration and recovery. To the resin thus obtained, 650 parts of propylene glycol monomethyl ether acetate was added, and after dissolution and concentration, 650 parts of propylene glycol monomethyl ether acetate was added and the mixture was concentrated again to obtain 190 parts of a propylene glycol monomethyl ether acetate solution of a resin (A3)-3 (solid content of 45%, yield of 75%). The weight-average molecular weight of the resin (A3)-3 was 3.79×10⁴.

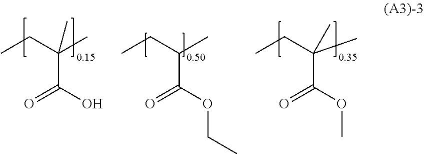

### Synthesis Example 5 [Synthesis of Resin (A3)-4]

In a four-necked flask equipped with a stirrer, a reflux condenser and a thermometer, 70 parts of ethyl acetate was added, and after temperature rise to 80° C., a mixture of 15 parts of methacrylic acid, 58 parts of ethyl acrylate, 41 parts of methyl methacrylate (molar ratio of methacrylic acid:ethyl acrylate:methyl methacrylate=15:50:35), 2.90 parts of 2,2′-azobis(2,4-dimethylvaleronitrile) and 100 parts of ethyl acetate was added dropwise over 2 hours. The mixture was stirred for 3 hours while maintaining at 80° C. to 85° C. The reaction mixture thus obtained was cooled to 40° C. or lower and diluted with 125 parts of ethyl acetate, and then a large amount of a mixed solution of ion-exchanged water and methanol to precipitate a resin, followed by filtration and recovery. To the resin thus obtained, 650 parts of propylene glycol monomethyl ether acetate was added, and after dissolution and concentration, 650 parts of propylene glycol monomethyl ether acetate was added and the mixture was concentrated again to obtain 180 parts of a propylene glycol monomethyl ether acetate solution of a resin (A3)-4 (solid content of 48%, yield of 75%). The weight-average molecular weight of the resin (A3)-4 was 2.36×10⁴.

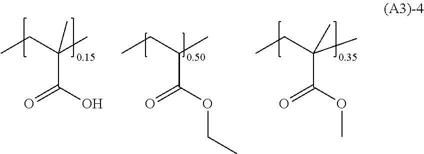

### <Preparation of Negative Resist Composition>

A mixture obtained by mixing and dissolving the respective components shown in Table 1 was filtered through a fluororesin filter having a pore diameter of 0.5 μm to prepare negative resist compositions.

TABLE 1

| | Resin (A1) | Acid | | | |
|---|---|---|---|---|---|
| Resist | Resin (A2) | generator | Crosslinking | Quencher | Solvent |
| composition | Resin (A3) | (B) | agent (E) | (C) | (D) |
| Composition | (A1)-1 = | (B)-1 = | (E)-1 = | (C)-1 = | (D)-1 = |
| 1 | 3.00 parts | 0.180 part | 1.456 parts | 0.025 parts | 16.4 parts |
| | (A2)-1 = | | | | (D)-2 = |
| | 6.50 parts | | | | 4.1 parts |
| | (A3)-1 = | | | | |
| | 4.00 parts | | | | |
| Composition | (A1)-1 = | (B)-1 = | (E)-1 = | (C)-1 = | (D)-1 = |
| 2 | 3.00 parts | 0.180 part | 1.456 parts | 0.025 part | 16.4 parts |
| | (A2)-1 = | | | | (D)-2 = |
| | 6.50 parts | | | | 4.1 parts |
| | (A3)-2 = | | | | |
| | 4.00 parts | | | | |
| Composition | (A1)-1 = | (B)-1 = | (E)-1 = | (C)-1 = | (D)-1 = |
| 3 | 3.00 parts | 0.180 part | 1.456 parts | 0.025 part | 16.4 parts |
| | (A2)-1 = | | | | (D)-2 = |
| | 6.50 parts | | | | 4.1 parts |
| | (A3)-3 = | | | | |
| | 4.00 parts | | | | |
| Composition | (A1)-1 = | (B)-1 = | (E)-1 = | (C)-1 = | (D)-1 = |
| 4 | 3.00 parts | 0.180 part | 1.456 parts | 0.025 part | 16.4 parts |
| | (A2)-1 = | | | | (D)-2 = |
| | 6.50 parts | | | | 4.1 parts |
| | (A3)-4 | | | | |
| | 4.00 parts | | | | |
| Composition | (A1)-1 = | (B)-1 = | (E)-2 = | (C)-1 = | (D)-1 = |
| 5 | 8.09 parts | 0.240 part | 1.246 parts | 0.024 part | 16.4 parts |
| | (A2)-1 = | | | | (D)-2 = |
| | 3.38 parts | | | | 4.1 parts |
| | (A3)-1 | | | | |
| | 2.03 parts | | | | |
| Composition | (A1)-1 = | (B)-1 = | (E)-2 = | (C)-1 = | (D)-1 = |
| 6 | 8.09 parts | 0.240 part | 1.246 parts | 0.030 part | 16.4 parts |
| | (A2)-2 = | | | | (D)-2 = |
| | 3.38 parts | | | | 4.1 parts |
| | (A3)-1 = | | | | |
| | 2.03 parts | | | | |
| Composition | (A1)-2 = | (B)-1 = | (E)-2 = | (C)-1 = | (D)-1 = |
| 7 | 8.09 parts | 0.240 part | 1.246 parts | 0.030 part | 16.4 parts |
| | (A2)-2 = | | | | (D)-2 = |
| | 3.38 parts | | | | 4.1 parts |
| | (A3)-2 = | | | | |
| | 2.03 parts | | | | |
| Composition | (A1)-1 = | (B)-1 = | (E)-1 = | (C)-1 = | (D)-1 = |
| 8 | 8.09 parts | 0.240 part | 1.456 parts | 0.038 part | 20.0 part |
| | (A2)-3 = | | | | (D)-3 = |
| | 3.38 parts | | | | 2.6 parts |
| | (A3)-1 = | | | | |
| | 2.03 parts | | | | |
| Composition | (A1)-1 = | (B)-2 = | (E)-2 = | (C)-1 = | (D)-1 = |
| 9 | 8.09 parts | 0.250 part | 1.246 parts | 0.020 part | 20.0 parts |
| | (A2)-2 = | | | | |
| | 3.38 parts | | | | |
| | (A3)-1 = | | | | |
| | 2.03 parts | | | | |
| Comparative | (A1)-1 = | (B)-1 = | (E)-1 = | (C)-1 = | (D)-1 = |
| Example | 9.45 parts | 0.240 part | 1.456 parts | 0.038 part | 20.0 part |
| composition | (A2)-3 = | | | | (D)-3 = |
| 1 | 4.05 parts | | | | 2.6 parts |
| Comparative | (A1)-1 = | (B)-1 = | (E)-1 = | (C)-1 = | (D)-1 = |
| Example | 6.75 parts | 0.240 part | 1.456 parts | 0.038 part | 20.0 parts |
| composition | (A2)-1 = | | | | |
| 2 | 6.75 parts | | | | |
| Comparative | (A1)-1 = | (B)-1 = | (E)-2 = | (C)-1 = | (D)-1 = |
| Example | 6.75 parts | 0.240 part | 1.246 parts | 0.030 part | 20.0 parts |
| composition | (A2)-1 = | | | | |
| 3 | 6.75 parts | | | | |

### <Resin (A1)>

(A1)-1: Resin (A1)-1

Resin including the following structural units, synthesized by the method mentioned in JP 2001-42529 A

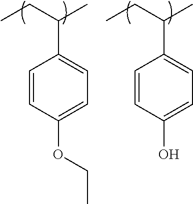

Weight-average molecular weight: 3,700

The proportion in which a hydroxyl group in poly-p-hydroxystyrene is substituted with an ethoxy group is 20.9%.
(A1)-2: Resin (A1)-2

Resin including the following structural units, synthesized by the method mentioned in JP 2001-42529 A

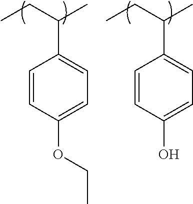

Weight-average molecular weight: 3,580

The proportion in which a hydroxyl group in poly-p-hydroxystyrene is substituted with an ethoxy group is 17.0%.

### <Novolak Resin (A2)>

(A2)-1: Resin (A2)-1

Resin including the following structural unit, synthesized by the method mentioned in JP 2001-42529 A

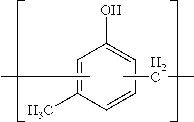

Weight-average molecular weight: 9,250
(A2)-2: Resin (A2)-2

Resin including the following structural unit, synthesized by the method mentioned in JP 2001-42529 A

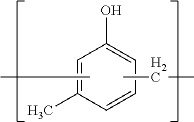

Weight-average molecular weight: 3,580
(A2)-3: Resin (A2)-3, weight-average molecular weight: 7,000 (Synthesis Example 1)

### <Resin (A3)>

(A3)-1: Resin (A3)-1, Weight-average molecular weight: 12,600 (Synthesis Example 2)
(A3)-2: Resin (A3)-2, Weight-average molecular weight: 9,940 (Synthesis Example 3)
(A3)-3: Resin (A3)-3, Weight-average molecular weight: 37,900 (Synthesis Example 4)
(A3)-4: Resin (A3)-4, Weight-average molecular weight: 23,600 (Synthesis Example 5)

### <Acid Generator (B)>

(B)-1: N-Hydroxynaphthalimide triflate (manufactured by Heraeus)

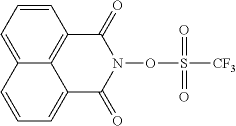 [SMILES: O=C1c2cccc3cccc(c23)C(=O)N1OS(=O)(=O)C(F)(F)F]

(B)-2: Compound represented by the following formula (manufactured by Heraeus)

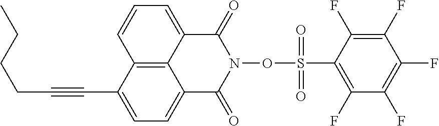 [SMILES: CCCCC#Cc1ccc2c3c(cccc13)C(=O)N(OS(=O)(=O)c1c(F)c(F)c(F)c(F)c1F)C2=O]

### <Crosslinking Agent (E)>

(E)-1: Compound represented by the following formula (manufactured by Heraeus)

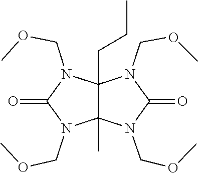

(E)-2: Compound represented by the following formula (manufactured by Heraeus)

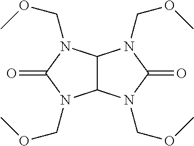

### <Quencher (C)>

(C)-1: 2,4,5-Triphenylimidazole (manufactured by Tokyo Chemical Industry Co., Ltd.)

### <Solvent (D)>

(D)-1: Propylene glycol monomethyl ether acetate
(D)-2: 2-Heptanone
(D)-3: Butyl acetate

### Examples 1 to 9, Comparative Examples 1 to 3

(Evaluation of Exposure of Negative Resist Composition with i-Ray)

On a 4-inch silicon wafer substrate, each of the above negative resist compositions was spin-coated so that the thickness of the resulting film became 9 μm after pre-baking.

Thereafter, the substrate was subjected to pre-baking on a direct hotplate at 120° C. for 90 seconds to form a composition layer.

Next, the silicon wafer with the composition layer formed on the wafer was then exposed through a mask for forming trench patterns (trench width of 1 to 2 μm) with changing exposure dose stepwise using an i-ray stepper (NSR-2005i9C, manufactured by Nikon Corporation, NA=0.5).

After exposure, each wafer was subjected to post-exposure baking on a hot plate at 110° C. for 60 seconds, and each wafer was subjected to paddle development for 180 seconds with an aqueous 2.38% by mass tetramethylammonium hydroxide solution to obtain resist patterns.

The resist patterns obtained after development were observed by a scanning electron microscope and the effective sensitivity was defined as the exposure dose at which trench patterns with a line width of 2 μm were obtained.

### <Evaluation of Resolution>

The resist pattern obtained at the effective sensitivity was observed by a scanning electron microscope, and the minimum line width of the resolved trench patterns was measured.

### <Evaluation of Residue>

Each trench pattern with a line width of 2 μm or 1.2 μm obtained at the effective sensitivity was observed by a scanning electron microscope. The case where no residue was observed in the pattern with a line width of 2 μm and the residue was observed in the pattern with a line width of 1.2 μm was rated “Fair”, and the case where no residue was observed in both patterns was rated “Good”.

### <Measurement of Dissolution Rate in Alkaline Developer (ADR)>

On a 4-inch silicon wafer substrate, each of the above negative resist compositions was spin-coated so that the thickness of the resulting film became 9 μm after pre-baking at 120° C. for 90 seconds, followed by baking at 110° C. for 60 seconds and further paddle development with an aqueous 2.38% by mass tetramethylammonium hydroxide solution for 30 seconds. The film thickness after development was measured, and the dissolution rate in alkaline developer (ADR) was calculated by the following formula.

$$ADR ( Å / sec ) = ( F 1 - F 2 ) / T$$

F1: Initial film thickness (film thickness after pre-baking) [Å]
F2: Film thickness after development [Å]
T: Development time [sec]

TABLE 2

| | Resist | Resolution | | |
|---|---|---|---|---|
| | composition | (μm) | Residue | ADR |
| Example 1 | Composition 1 | 1.2 | Good | 2,000 |
| Example 2 | Composition 2 | 1.2 | Good | 1,488 |
| Example 3 | Composition 3 | 1.2 | Fair | 1,123 |
| Example 4 | Composition 4 | 1.2 | Fair | 953 |
| Example 5 | Composition 5 | 1.2 | Good | 1,279 |
| Example 6 | Composition 6 | 1.2 | Good | 1,795 |
| Example 7 | Composition 7 | 1.2 | Good | 2,262 |
| Example 8 | Composition 8 | 1.2 | Good | 1,301 |
| Example 9 | Composition 9 | 1.2 | Good | 1,800 |
| Comparative | Comparative | 1.6 | —* | 700 |
| Example 1 | Example | | | |
| | composition 1 | | | |
| Comparative | Comparative | 1.6 | —* | 800 |
| Example 2 | Example | | | |
| | composition 2 | | | |
| Comparative | Comparative | 1.6 | —* | 820 |
| Example 3 | Example | | | |
| | composition 3 | | | |

*not evaluated

In all Examples 1 to 9, the resolution after development was satisfactory at 1.2 μm, but in all Comparative Examples 1 to 3, the resolution was poor at 1.6 μm.

In Examples 1 to 9, no residue was generated at least in the pattern with a line width of 2 μm. In particular, in Examples 1 to 2 and 5 to 9, no residue was generated in each pattern with a line width 2 μm or 1.2 μm. In Comparative Examples 1 to 3, the resolution was 1.6 μm, and the pattern with a line width of 1.2 μm was not resolved, so that the residue was not evaluated.

Examples 1 to 9 had a larger ADR and a higher dissolution rate in alkaline developer than Comparative Examples 1 to 3.

The negative resist composition of the present invention is capable of forming a resist pattern with excellent resolution and is therefore suited for fine processing of semiconductors.

What is claimed is:

1. A negative resist composition comprising a resin (A1) including a structural unit represented by formula (a2-1) and a structural unit represented by formula (a2-4), a novolak resin (A2), a resin (A3) including a structural unit represented by formula (a3-1) and a structural unit represented by formula (a3-2), a crosslinking agent (E) and an acid generator (B): 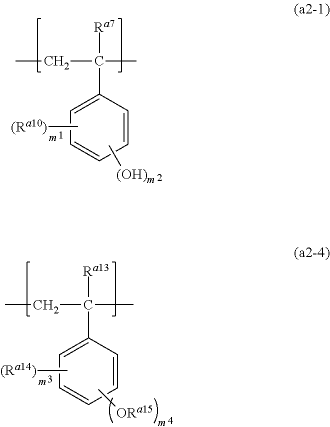
wherein, in formula (a2-1) and formula (a2-4),
R^{a7} and R^{a13} each independently represent a hydrogen atom or a methyl group,
R^{a10} and R^{a14} each independently represent an alkyl group having 1 to 6 carbon atoms,
R^{a15} represents a hydrocarbon group having 1 to 12 carbon atoms, and a methylene group included in the hydrocarbon group may be replaced by an oxygen atom or a carbonyl group,
m¹ represents an integer of 0 to 4, and when m¹ is 2 or more, a plurality of R^{a10} may be the same or different from each other,
m² represents an integer of 1 to 4,
in which the total of m¹ and m² is 5 or less,
m³ represents an integer of 0 to 4, and when m³ is 2 or more, a plurality of R^{a14} may be the same or different from each other, and
m⁴ represents an integer of 1 to 4, and when m⁴ is 2 or more, a plurality of R^{a15} may be the same or different from each other,
in which the total of m³ and m⁴ is 5 or less, and: 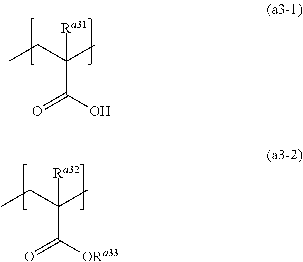
wherein, in formula (a3-1) and formula (a3-2),
R^{a31} and R^{a32} each independently represent a hydrogen atom or a methyl group, and
R^{a33} represents an alkyl group having 1 to 12 carbon atoms, and a methylene group included in the alkyl group may be replaced by an oxygen atom.

2. The negative resist composition according to claim 1, wherein the acid generator (B) is a compound having a group represented by formula (B1): 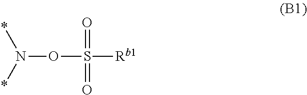
wherein, in formula (B1),
R^{b1} represents a hydrocarbon group having 1 to 18 carbon atoms which may have a fluorine atom, and a methylene group included in the hydrocarbon group may be replaced by an oxygen atom or a carbonyl group, and * represents a bond.

3. The negative resist composition according to claim 1, wherein the resin (A3) is composed of a structural unit represented by formula (a3-1) and a structural unit represented by formula (a3-2).

4. The negative resist composition according to claim 1, wherein the crosslinking agent (E) is a melamine-based crosslinking agent or a glycoluril-based crosslinking agent.

5. A method for producing a resist pattern, which comprises:
(1) a step of applying the negative resist composition according to claim 1 on a substrate,
(2) a step of drying the applied composition to form a composition layer,
(3) a step of exposing the composition layer, and
(4) a step of heating and developing the exposed composition layer.
